(19) United States
(12) Patent Application Publication
(10) Pub. No.: US 2026/0328849 A1
(43) Pub. Date: Oct. 22, 2026

(54) INFORMATION PROCESSING METHOD, INFORMATION PROCESSING DEVICE, AND NON-TRANSITORY COMPUTER READABLE RECORDING MEDIUM STORING INFORMATION PROCESSING PROGRAM

(71) Applicant: PANASONIC INTELLECTUAL PROPERTY MANAGEMENT CO., LTD., Osaka (JP)

(72) Inventors: Takashi HASHIMOTO, Hyogo (JP); Yuki HAYASHI, Osaka (JP)

(21) Appl. No.: 19/648,499

(22) Filed: Apr. 15, 2026

Related U.S. Application Data
(63) Continuation of application No. PCT/JP2024/026580, filed on Jul. 25, 2024.

(30) Foreign Application Priority Data
Oct. 16, 2023 (JP) 2023-178492

(51) Int. Cl. G01R 31/382; G01R 31/396

(52) U.S. Cl. CPC G01R 31/382; G01R 31/396

(57) ABSTRACT

An information terminal acquires a plurality of abnormal state items indicating a state item in which an abnormal value is detected among a plurality of state items indicating a plurality of states of a plurality of batteries, and displays the plurality of acquired abnormal state items and displays a monitored state item, which is an abnormal state item that needs to be handled, among the plurality of abnormal state items, in a mode different from other abnormal state items.

### FIELD OF INVENTION

The present disclosure relates to a technique of displaying a state item in which an abnormal value is detected among a plurality of state items indicating a plurality of states of a battery.

### BACKGROUND ART

For example, Patent Literature 1 discloses that a battery that is abnormally deteriorated is diagnosed from an operating history of the battery and a model, and a coefficient of an item that is out of a constraint condition is displayed in a highlighted manner.

However, in the conventional technique described above, only an item determined to be abnormal is displayed in a highlighted manner, and further improvement has been required.

Patent Literature 1: JP 2018-169161 A

### SUMMARY OF THE INVENTION

The present disclosure has been made to solve the above problem, and an object of the present disclosure is to provide a technique capable of supporting a user's determination of an error that has occurred in a battery.

An information processing method according to the present disclosure is an information processing method in a computer, the information processing method including acquiring a plurality of abnormal state items indicating a state item in which an abnormal value is detected among a plurality of state items indicating a plurality of states of a plurality of batteries, and displaying the plurality of abnormal state items and displaying a monitored state item, which is an abnormal state item that needs to be handled, among the plurality of abnormal state items, in a mode different from other abnormal state items.

According to the present disclosure, it is possible to support determination of an error occurring in a battery by the user.

### BRIEF DESCRIPTION OF THE DRAWINGS

FIG. 1 is a diagram illustrating an overall configuration of a battery management system in an embodiment of the present disclosure.

FIG. 2 is a sequence diagram for describing operation of the battery management system in the embodiment of the present disclosure.

FIG. 3 is a diagram illustrating an example of a table in which an abnormal state item, an error item, and an importance level are associated with each other in the present embodiment.

FIG. 4 is a diagram illustrating an example of an abnormal state item display screen displaying a plurality of abnormal state items of a plurality of batteries in the present embodiment.

FIG. 5 is a diagram illustrating an example of an abnormal state item display screen displaying a plurality of abnormal state items of a plurality of batteries in Modification Example 1 of the present embodiment.

FIG. 6 is a diagram illustrating an example of an abnormal state item display screen displaying a plurality of abnormal state items of a plurality of batteries in Modification Example 2 of the present embodiment.

FIG. 7 is a sequence diagram for describing operation of the battery management system in Modification Example 3 of the embodiment of the present disclosure.

FIG. 8 is a diagram illustrating an example of an abnormal state item display screen displaying a list of a plurality of abnormal state items in Modification Example 3 of the present embodiment.

FIG. 9 is a flowchart for describing abnormality degree assignment processing of a server in Modification Example 4 of the embodiment of the present disclosure.

FIG. 10 is a schematic diagram for describing a first assignment method of abnormality degree in Modification Example 4 of the present embodiment.

FIG. 11 is a schematic diagram for describing a second assignment method of abnormality degree in Modification Example 4 of the present embodiment.

FIG. 12 is a diagram for describing abnormality degree assigned to a plurality of state items of one battery in Modification Example 4 of the present embodiment.

FIG. 13 is a diagram illustrating an example of a table in which a plurality of state items of one battery, the number of abnormality occurrences, and a threshold are associated with each other in Modification Example 5 of the present embodiment.

FIG. 14 is a flowchart for describing abnormality degree assignment processing of the server in Modification Example 5 of the embodiment of the present disclosure.

FIG. 15 is a flowchart for describing abnormality degree assignment processing of the server in Modification Example 6 of the embodiment of the present disclosure.

FIG. 16 is a diagram illustrating an example of a table in which a plurality of state items of one battery, a plurality of periods, the number of abnormality occurrences, and a threshold are associated with each other in Modification Example 5 and Modification Example 6 of the present embodiment.

FIG. 17 is a flowchart for describing abnormality degree assignment processing of the server in Modification Example 7 of the embodiment of the present disclosure.

FIG. 18 is a diagram for describing elapsed time in Modification Example 7 of the present embodiment.

FIG. 19 is a diagram illustrating an example of a table in which a plurality of state items of one battery, the number of abnormality occurrence continuation days, and a threshold are associated with each other in Modification Example 8 of the present embodiment.

FIG. 20 is a flowchart for describing abnormality degree assignment processing of the server in Modification Example 9 of the embodiment of the present disclosure.

FIG. 21 is a diagram illustrating an example of an abnormal state item display screen displaying a plurality of abnormal state items and a plurality of monitored state items in Modification Example 10 of the present embodiment.

FIG. 22 is a diagram illustrating an example of an operation history display screen displaying an operation history of a monitored state item and a plurality of abnormal state items in Modification Example 11 of the present embodiment.

FIG. 23 is a diagram illustrating a first display example of an operation history display screen displaying operation histories of a plurality of monitored state items and a plurality of abnormal state items in Modification Example 12 of the present embodiment.

FIG. 24 is a diagram illustrating a second display example of an operation history display screen displaying operation histories of a plurality of monitored state items and a plurality of abnormal state items in Modification Example 12 of the present embodiment.

FIG. 25 is a diagram illustrating a third display example of an operation history display screen displaying operation histories of a plurality of monitored state items and a plurality of abnormal state items in Modification Example 12 of the present embodiment.

FIG. 26 is a diagram illustrating a fourth display example of an operation history display screen displaying operation histories of a plurality of monitored state items and a plurality of abnormal state items in Modification Example 12 of the present embodiment.

### DETAILED DESCRIPTION

### Knowledge Underlying Present Disclosure

As described above, in the conventional technique, an item determined to be abnormal is displayed in a highlighted manner. Since a plurality of types of abnormalities may occur in a battery, if there is an abnormal item occurring in the same battery in addition to deterioration of the battery, it is necessary to check the abnormal item. However, in the conventional technique, information about a plurality of abnormal items that occur in a battery is not displayed in a list. Further, even if a plurality of abnormal items are displayed in a list, which abnormal item among the plurality of abnormal items should be monitored is not displayed, and thus it is difficult to support determination by the user on an error that occurs in a battery.

In order to solve the above problem, a technique below is disclosed.
(1) An information processing method according to one aspect of the present disclosure is an information processing method in a computer, the information processing method including acquiring a plurality of abnormal state items indicating a state item in which an abnormal value is detected among a plurality of state items indicating a plurality of states of a plurality of batteries, and displaying the plurality of abnormal state items and displaying a monitored state item, which is an abnormal state item that needs to be handled, among the plurality of abnormal state items, in a mode different from other abnormal state items.

According to this configuration, since a monitored state item, which is an abnormal state item that needs to be handled among a plurality of abnormal state items, is displayed in a mode different from other abnormal state items, the user can immediately recognize which abnormal state item needs to be handled among a plurality of displayed abnormal state items, and it is possible to support determination of an error that occurs in a battery by the user. Further, since a plurality of abnormal state items that occur in a plurality of batteries can be transmitted to the user with minimum display, resources required for display can be reduced.
(2) The information processing method according to (1) above may further include identifying one battery from among the plurality of batteries, and the display may include displaying the plurality of abnormal state items of the one battery and displaying the monitored state item among the plurality of abnormal state items in a mode different from the other abnormal state items.

According to this configuration, since the number of a plurality of abnormal state items and monitored state items to be displayed can be reduced, work of checking a monitored state item by the user can be shortened, and it is possible to support determination of an error that occurs in a battery by the user.
(3) The information processing method according to (1) or (2) above may further include determining, based on a table in which at least one first abnormal state item among the plurality of abnormal state items is associated with at least one second abnormal state item that is the monitored state item, the at least one second abnormal state item associated with the at least one first abnormal state item included in the plurality of abnormal state items as at least one monitored state item.

According to this configuration, since at least one second abnormal state item associated with at least one first abnormal state item among a plurality of acquired abnormal state items is determined as at least one monitored state item, at least one monitored state item can be easily determined.
(4) The information processing method according to (1) or (2) above may further include determining, based on a table in which at least one abnormal state item among the plurality of abnormal state items, an error item indicating an error that occurs in a battery predicted from the at least one abnormal state item, and an importance level of the error item are associated with each other, at least one abnormal state item associated with the error item having the highest importance level among the plurality of acquired abnormal state items as at least one monitored state item.

According to this configuration, since at least one abnormal state item associated with an error item having the highest importance level among a plurality of acquired abnormal state items is determined as at least one monitored state item, at least one monitored state item with the highest priority and necessary for determining an error that occurs in a battery can be presented to the user.
(5) In the information processing method according to (1) or (2) above, abnormality degree indicating degree of abnormality may be associated with each of the plurality of abnormal state items, and the information processing method may further include determining at least one abnormal state item having the maximum abnormality degree among the plurality of acquired abnormal state items as at least one monitored state item.

According to this configuration, since at least one abnormal state item having the maximum abnormality degree among a plurality of acquired abnormal state items is determined as at least one monitored state item, at least one monitored state item having the highest degree of abnormality and necessary for determining an error that occurs in a battery can be presented to the user.
(6) In the information processing method according to (5) above, the abnormality degree of each of the plurality of abnormal state items may be determined based on degree to which an operation history of each of the plurality of abnormal state items exceeds a threshold.

According to this configuration, abnormality degree of an abnormal state item can be determined based on degree to which an operation history of the abnormal state item exceeds the threshold.
(7) In the information processing method according to (5) above, the abnormality degree of each of the plurality of abnormal state items may be determined based on time during which an operation history of each of the plurality of abnormal state items continuously exceeds a threshold.

According to this configuration, abnormality degree of an abnormal state item can be determined based on time during which an operation history of the abnormal state item continuously exceeds the threshold.
(8) In the information processing method according to (5) above, the number of occurrences of the plurality of abnormal state items in a first predetermined period may be counted, and the abnormality degree of each of the plurality of abnormal state items may be determined based on degree to which the number of occurrences exceeds a threshold.

According to this configuration, abnormality degree is determined based on degree to which the number of occurrences exceeds the threshold. Therefore, for example, an abnormal state item having a large number of occurrences can be preferentially presented to the user.
(9) In the information processing method according to (8) above, one year may be divided into a plurality of periods, and one threshold may be selected from among a plurality of different thresholds for each of the plurality of periods according to which of the plurality of periods the first predetermined period is included.

According to this configuration, for example, a threshold corresponding to a season can be selected from a plurality of thresholds.
(10) In the information processing method according to (8) above, the number of occurrences of the plurality of abnormal state items in a second predetermined period longer than the first predetermined period may be counted, and the abnormality degree of each of the plurality of abnormal state items may be decreased in a case where the number of occurrences exceeds a threshold, and may be increased in a case where the number of occurrences does not exceed the threshold.

According to this configuration, in a case where the number of occurrences of an abnormal state item exceeds the threshold in the second predetermined period longer than the first predetermined period, that is, in a case where an occurrence frequency of the abnormal state item is high, abnormality degree of the abnormal state item decreases, and in a case where the number of occurrences of an abnormal state item does not exceed the threshold in the second predetermined period, that is, in a case where an occurrence frequency of the abnormal state item is low, abnormality degree of the abnormal state item increases. Therefore, since abnormality degree of an abnormal state item having a low occurrence frequency is higher than abnormality degree of an abnormal state item having a high occurrence frequency, the abnormal state item having a low occurrence frequency can be preferentially presented to the user.
(11) In the information processing method according to (1) or (2) above, abnormality degree indicating degree of abnormality may be associated with each of the plurality of abnormal state items, and the information processing method may further include determining at least one abnormal state item having the abnormality degree equal to or more than a threshold among the plurality of acquired abnormal state items as at least one monitored state item.

According to this configuration, since at least one abnormal state item having abnormality degree equal to or more than the threshold is determined as a monitored state item among a plurality of acquired abnormal state items, at least one monitored state item having abnormality degree equal to or more than the threshold and necessary for determining an error that occurs in a battery can be presented to the user.
(12) In the information processing method according to (11) above, the display may include displaying each of a plurality of monitored state items in a different mode according to a level of the abnormality degree associated with each of the plurality of monitored state items in a case where the plurality of monitored state items is determined.

According to this configuration, each of a plurality of monitored state items is displayed in a different mode according to a level of abnormality degree associated with each of a plurality of monitored state items, so that the user can easily determine each of the plurality of monitored state items.
(13) The information processing method according to (2) may further include acquiring an operation history of each of the plurality of abnormal state items, and the display may include displaying a plurality of operation histories of the plurality of abnormal state items of the one battery, and displaying an operation history of the monitored state item among the plurality of operation histories in a mode different from the other operation histories.

According to this configuration, since an operation history of a monitored state item among a plurality of operation histories is displayed in a mode different from other operation histories, it is possible to attract the line of sight of the user to the operation history of the monitored state item. Further, since an operation history of a monitored state item is presented to the user, the user can check the operation history of the monitored state item and more accurately determine what type of error occurs in a battery.

Further, the present disclosure can be realized not only as the information processing method for executing the characteristic processing as described above, but also as an information processing device or the like having a characteristic configuration corresponding to characteristic processing executed by the information processing method. Further, the present disclosure can also be realized as a computer program that causes a computer to execute characteristic processing included in the information processing method described above. Therefore, an effect similar to the effect in the above information processing method can also be achieved by another aspect described below.
(14) An information processing device according to another aspect of the present disclosure includes an acquisition part that acquires a plurality of abnormal state items indicating a state item in which an abnormal value is detected among a plurality of state items indicating a plurality of states of a plurality of batteries, and a display part that displays the plurality of abnormal state items and displays a monitored state item, which is an abnormal state item that needs to be handled, among the plurality of abnormal state items, in a mode different from other abnormal state items.
(15) An information processing program according to another aspect of the present disclosure causes a computer to function to acquire a plurality of abnormal state items indicating a state item in which an abnormal value is detected among a plurality of state items indicating a plurality of states of a plurality of batteries, and display the plurality of abnormal state items and display a monitored state item, which is an abnormal state item that needs to be handled, among the plurality of abnormal state items, in a mode different from other abnormal state items.
(16) A non-transitory computer-readable recording medium according to another aspect of the present disclosure records an information processing program, and the information processing program causes a computer to function to acquire a plurality of abnormal state items indicating a state item in which an abnormal value is detected among a plurality of state items indicating a plurality of states of a plurality of batteries, and display the plurality of abnormal state items and display a monitored state item, which is an abnormal state item that needs to be handled, among the plurality of abnormal state items, in a mode different from other abnormal state items.

Hereinafter, an embodiment of the present disclosure will be described with reference to the accompanying drawings. Note that the embodiment described below shows one specific example of the present disclosure. Numerical values, shapes, components, steps, order of steps, and the like of the embodiment below are merely examples, and are not intended to limit the present disclosure. Further, a component not described in an independent claim representing a highest concept among components in the embodiment below is described as an optional component. Further, in all the embodiments, content of each of the embodiments can be combined.

### Embodiment

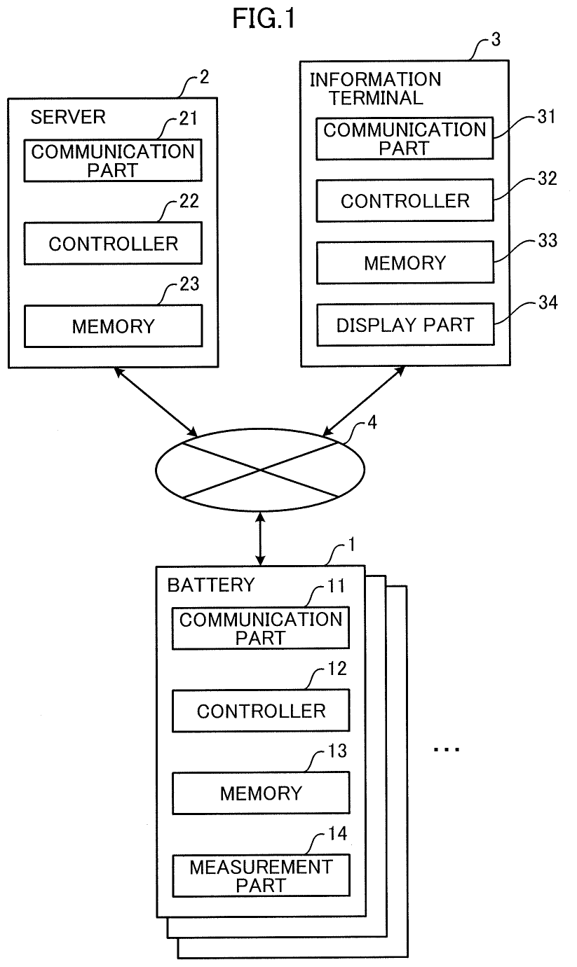

FIG. 1 is a diagram illustrating an overall configuration of a battery management system in an embodiment of the present disclosure.

The battery management system illustrated in FIG. 1 includes a plurality of batteries 1, a server 2, and an information terminal 3.

The battery 1 includes a plurality of secondary batteries, and stores electric power by charging, and supplies electric power by discharging. The secondary battery is, for example, a lead acid battery or a lithium ion battery. The battery 1 is a battery pack including a plurality of battery cells. The battery 1 is mounted as a power source on various devices. The battery 1 is mounted on an electric mobile body such as an electric vehicle, for example.

The battery 1 includes a communication part 11, a controller 12, a memory 13, and a measurement part 14.

The measurement part 14 measures a plurality of state items of the battery 1. The measurement part 14 measures, for example, a plurality of state items such as a Field Effect Transistor (FET) temperature, a cell temperature, a pack temperature, an ambient temperature, a cell current, a cell voltage, a pack current, a pack voltage, a pack resistance, the number of times of charging, a cumulative charge amount, a cumulative discharge amount, a pack full charge amount, and a State Of Charge (SOC). The measurement part 14 stores measured values of the plurality of state items in the memory 13. Note that the plurality of state items are not limited to the above items, and may be simply a battery temperature, a battery current, or a battery voltage, or may be use time of the battery 1, a travel distance of an electric mobile body on which the battery 1 is mounted, or the like.

The memory 13 is, for example, a storage device, such as a Random Access Memory (RAM), a Solid State Drive (SSD), or a flash memory, capable of storing various types of information. The memory 13 stores an operation history of a plurality of state items measured by the measurement part 14.

The controller 12 is, for example, a central processing unit (CPU), reads an operation history of a plurality of state items from the memory 13, and creates battery log information including a battery ID for identifying the battery 1 and the read operation history of the plurality of state items. The controller 12 outputs the created battery log information to the communication part 11.

The communication part 11 transmits battery log information of the battery 1 to the server 2. The battery log information includes a battery ID of the battery 1 and an operation history of a plurality of state items of the battery 1. The communication part 11 periodically transmits the battery log information to the server 2. For example, the communication part 11 may transmit the battery log information including an operation history of a plurality of state items measured for one minute to the server 2 every one minute.

Although the battery 1 includes the communication part 11, the controller 12, the memory 13, and the measurement part 14 in the present embodiment, the present disclosure is not limited to this configuration, and a device on which the battery 1 is mounted may include the communication part 11, the controller 12, the memory 13, and the measurement part 14.

The server 2 is communicably connected to a plurality of the batteries 1 and the information terminal 3 via a network 4. The network 4 is the Internet, for example.

The server 2 includes a communication part 21, a controller 22, and a memory 23.

The communication part 21 receives the battery log information transmitted by the battery 1. The communication part 21 outputs the received battery log information to the controller 22.

The memory 23 is a storage device, such as a RAM, an SSD, a Hard Disk Drive (HDD), or a flash memory, capable of storing various types of information. The memory 23 stores the battery log information. The memory 23 stores an operation history of a plurality of state items in association with a battery ID. The memory 23 stores an operation history of a plurality of state items of each of a plurality of the batteries 1.

Further, the memory 23 stores a table in which at least one abnormal state item among a plurality of abnormal state items indicating a state item in which an abnormal value is detected, an error item indicating an error that occurs in a battery predicted from the at least one abnormal state item, and an importance level of the error item are associated with each other. The abnormal value indicates a value exceeding a threshold. The threshold varies depending on a state item.

The communication part 21 transmits, to the information terminal 3, a plurality of abnormal state items indicating state items in which an abnormal value is detected from among a plurality of state items indicating a plurality of states of a plurality of the batteries 1.

The controller 22 is, for example, a CPU. The controller 22 stores the battery log information received by the communication part 21 in the memory 23. From the battery log information stored in the memory 23, the controller 22 extracts a plurality of abnormal state items indicating state items in which an abnormal value is detected among a plurality of state items indicating a plurality of states of a plurality of batteries. The controller 22 determines a monitored state item which is an abnormal state item that needs to be handled among a plurality of abnormal state items. Based on a table stored in the memory 23, the controller 22 determines, as at least one monitored state item, at least one abnormal state item associated with an error item with the highest importance level among a plurality of abnormal state items. The controller 22 sets a display mode of a monitored state item among a plurality of abnormal state items to be different from display modes of other abnormal state items.

The communication part 21 transmits a plurality of abnormal state items whose display modes are set by the controller 22 to the information terminal 3.

The information terminal 3 is, for example, a smartphone, a tablet computer, or a personal computer, and is used by a manager (user) who manages a plurality of the batteries 1.

The information terminal 3 includes a communication part 31, a controller 32, a memory 33, and a display part 34.

The communication part 31 receives a plurality of abnormal state items transmitted by the server 2. That is, the communication part 31 acquires a plurality of abnormal state items indicating state items in which an abnormal value is detected from among a plurality of state items indicating a plurality of states of a plurality of the batteries 1.

The controller 32 is, for example, a CPU. The controller 32 controls the display part 34 to display a list of a plurality of abnormal state items received by the communication part 31. Further, the controller 32 controls the display part 34 to display a monitored state item, which is an abnormal state item that needs to be handled among a plurality of abnormal state items, in a mode different from other abnormal state items.

The display part 34 is, for example, a touch panel, and displays a list of a plurality of abnormal state items received by the communication part 31. At this time, the display part 34 displays the plurality of abnormal state items, and displays a monitored state item among the plurality of abnormal state items in a mode different from other abnormal state items.

The memory 33 is, for example, a storage device that can store various types of information, such as a RAM, an SSD, an HDD, or a flash memory. The memory 33 stores a plurality of abnormal state items of a plurality of the batteries 1 received by the communication part 31.

Note that although the battery management system in the present embodiment includes a plurality of the batteries 1, the server 2, and the information terminal 3, the present disclosure is not limited to this configuration, and the battery management system may include a plurality of the batteries 1 and the information terminal 3 without including the server 2. In this case, the information terminal 3 has a function of the server 2.

Next, operation of the battery management system in the embodiment of the present disclosure will be described.

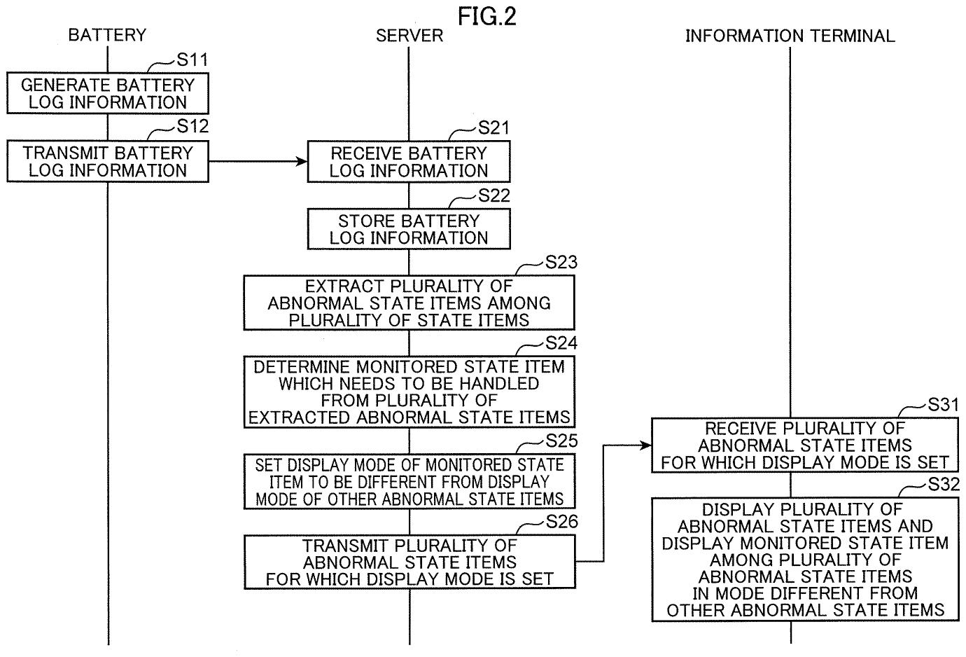

FIG. 2 is a sequence diagram for describing operation of the battery management system in the embodiment of the present disclosure.

First, in Step S11, the controller 12 of the battery 1 creates the battery log information including a battery ID and an operation history of a plurality of state items.

Next, in Step S12, the communication part 11 of the battery 1 transmits the battery log information of the battery 1 created by the controller 12 to the server 2. The battery management system includes a plurality of the batteries 1. For this reason, each of a plurality of the batteries 1 transmits the battery log information to the server 2.

Next, in Step S21, the communication part 21 of the server 2 receives the battery log information transmitted by the battery 1. The communication part 21 receives a plurality of pieces of the battery log information transmitted by a plurality of the batteries 1.

Next, in Step S22, the controller 22 of the server 2 stores the battery log information received by the communication part 21 in the memory 23. The controller 22 stores the battery log information of a plurality of the batteries 1 in the memory 23.

Next, in Step S23, the controller 22 extracts a plurality of abnormal state items in which an abnormal value is detected among a plurality of state items included in the battery log information stored in the memory 23. Note that each of the plurality of abnormal state items is associated with which battery the abnormal state item pertains to.

Note that a temporal range in which a plurality of abnormal state items are extracted from the battery log information can be changed, and a change by the user may be accepted. For example, in a case where an error occurs in December, there is a high possibility that data of March is unnecessary. Therefore, the controller 22 may extract a plurality of abnormal state items from the battery log information for the latest October-December period.

Next, in Step S24, the controller 22 determines a monitored state item which is an abnormal state item that needs to be handled among the plurality of extracted abnormal state items.

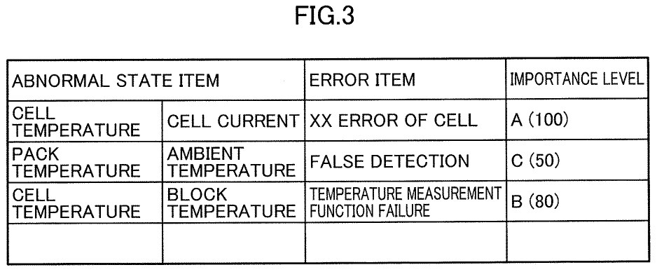

FIG. 3 is a diagram illustrating an example of a table in which an abnormal state item, an error item, and an importance level are associated with each other in the present embodiment.

The memory 23 stores a table in which at least one abnormal state item among a plurality of abnormal state items, an error item indicating an error that occurs in a battery predicted from the at least one abnormal state item, and an importance level of the error item are associated with each other.

For example, two abnormal state items of cell temperature and cell current are associated with an error item of a battery which is “XX error of cell”. That is, in a case where an abnormal value is detected in both cell temperature and cell current, it is predicted that an error “XX error of cell” has occurred in the battery 1. Further, two abnormal state items of pack temperature and ambient temperature are associated with an error item of a battery which is “false detection”. That is, when an abnormal value is detected in both pack temperature and ambient temperature, it is predicted that an error of “false detection” has occurred in the battery 1. Further, two abnormal state items of cell temperature and block temperature are associated with an error item of a battery which is “temperature measurement function failure”. That is, in a case where an abnormal value is detected in both cell temperature and block temperature, it is predicted that an error of “temperature measurement function failure” has occurred in the battery 1.

Further, an error item is associated with an importance level according to degree of error. For example, the importance level of “XX error of cell” is A rank, the importance level of “false detection” is C rank, and the importance level of “temperature measurement function failure” is B rank. A rank is the highest importance level, B rank is the second highest importance level, and C rank is the third highest importance level. Note that the importance level may be represented by a numerical value instead of being represented by a rank. For example, the importance level of “XX error of cell” may be 100, the importance level of “false detection” may be 50, and the importance level of “temperature measurement function failure” may be 80.

Based on a table stored in the memory 23, the controller 22 determines, as at least one monitored state item, at least one abnormal state item associated with an error item with the highest importance level among a plurality of abnormal state items. In the example illustrated in FIG. 3, since the importance level of “XX error of cell” is the highest, cell temperature and cell current associated with “XX error of cell” are determined as monitored state items.

Note that, in a case where there are a plurality of error items having the highest importance level, the controller 22 may determine a plurality of abnormal state items associated with the plurality of error items having the highest importance level among a plurality of abnormal state items as a plurality of monitored state items.

Further, in a case where there are a plurality of error items having the highest importance level, the controller 22 may determine at least one abnormal state item associated with one error item among the plurality of error items having the highest importance level among a plurality of abnormal state items as at least one monitored state item. In this case, the controller 22 may randomly select one error item from the plurality of error items having the highest importance level. Further, the controller 22 may select one error item at the top in a table from among the plurality of error items having the highest importance level.

Further, in the present embodiment, the controller 22 determines at least one abnormal state item associated with an error item having the highest importance level among a plurality of abnormal state items as at least one monitored state item, but the present disclosure is not particularly limited to this. The controller 22 may determine, as at least one monitored state item, at least one abnormal state item associated with an error item having an importance level equal to or more than a threshold. For example, in a case where the threshold is B rank (80), the controller 22 determines cell temperature and cell current associated with “XX error of cell” and cell temperature and block temperature associated with “temperature measurement function failure” as monitored state items.

In a case where the number of error items is large, an importance level is represented by a numerical value, so that the threshold can be finely set, and the number of monitored state items can be narrowed down.

Further, in the present embodiment, the memory 23 may store a table in which at least one first abnormal state item among a plurality of abnormal state items is associated with at least one second abnormal state item that is a monitored state item. The controller 22 may determine at least one second abnormal state item associated with at least one first abnormal state item included in a plurality of abnormal state items as at least one monitored state item based on the table. For example, one second abnormal state item of FET temperature may be associated with two first abnormal state items of cell temperature and cell current. In a case where a plurality of abnormal state items include two first abnormal state items of cell temperature and cell current, the controller 22 may determine one second abnormal state item of FET temperature associated with the two first abnormal state items of cell temperature and cell current as a monitored state item. Note that at least one first abnormal state item and at least one second abnormal state item may be the same or different.

Further, in the present embodiment, the memory 23 may store in advance at least one abnormal state item that is a monitored state item among a plurality of abnormal state items. The controller 22 may determine at least one predetermined abnormal state item among a plurality of abnormal state items as at least one monitored state item.

Returning to FIG. 2, next, in Step S25, the controller 22 sets a display mode of the monitored state item among a plurality of abnormal state items of a plurality of the batteries 1 to be different from display modes of other abnormal state items.

Next, in Step S26, the communication part 21 transmits, to the information terminal 3, a plurality of abnormal state items of a plurality of the batteries 1 whose display modes are set by the controller 22.

Next, in Step S31, the communication part 31 of the information terminal 3 receives the plurality of abnormal state items of a plurality of the batteries 1 whose display modes are set, the plurality of abnormal state items being transmitted by the server 2.

Next, in Step S32, the display part 34 displays the plurality of abnormal state items of a plurality of the batteries 1 received by the communication part 31, and displays the monitored state item among the plurality of abnormal state items in a mode different from other abnormal state items.

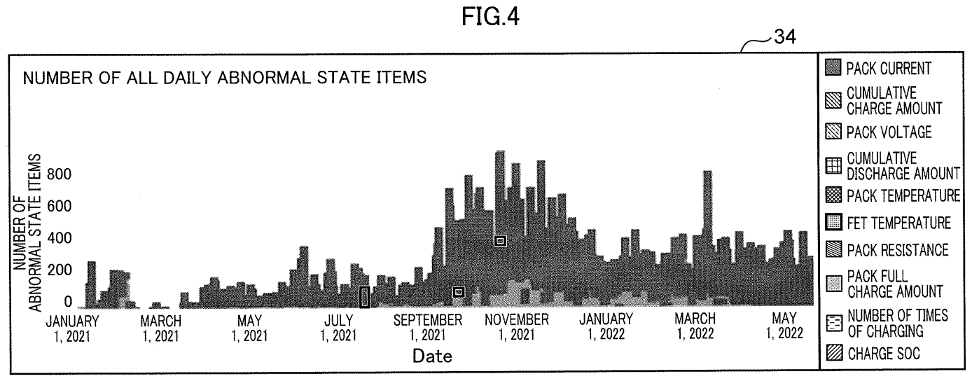

FIG. 4 is a diagram illustrating an example of an abnormal state item display screen displaying a plurality of abnormal state items of a plurality of the batteries 1 in the present embodiment.

The display part 34 displays the abnormal state item display screen illustrated in FIG. 4. The abnormal state item display screen includes a bar graph indicating the number of abnormal state items occurring in a predetermined period. The vertical axis represents the number of abnormal state items, and the horizontal axis represents year, month, and day. The bar graphs are stacked by being color-coded in accordance with abnormal state items.

For example, the abnormal state item includes pack current, a cumulative charge amount, pack voltage, a cumulative discharge amount, pack temperature, FET temperature, pack resistance, a pack full charge amount, the number of times of charging, and a charge SOC. A legend for describing a color corresponding to an abnormal state item is displayed next to a bar graph. For example, the color corresponding to pack current is blue, the color corresponding to a cumulative charge amount is purple, the color corresponding to pack voltage is green, and the color corresponding to a cumulative discharge amount is yellow.

Further, the display part 34 displays a monitored state item among a plurality of abnormal state items of a plurality of the batteries 1 in a mode different from other abnormal state items. In FIG. 4, the monitored state item is FET temperature. The display part 34 highlights the monitored state item. The display part 34 highlights the monitored state item by surrounding the periphery of the monitored state item with a frame of a predetermined color. The predetermined color is, for example, red.

The display part 34 may highlight the monitored state item by blinking the monitored state item. Further, the display part 34 may highlight the monitored state item by displaying the monitored state item in a chromatic color such as red and displaying other abnormal state items in an achromatic color such as white, gray, or black.

Note that, in Modification Example 1 of the present embodiment, the display part 34 may display a monitored state item on the lower side of a stacked bar graph.

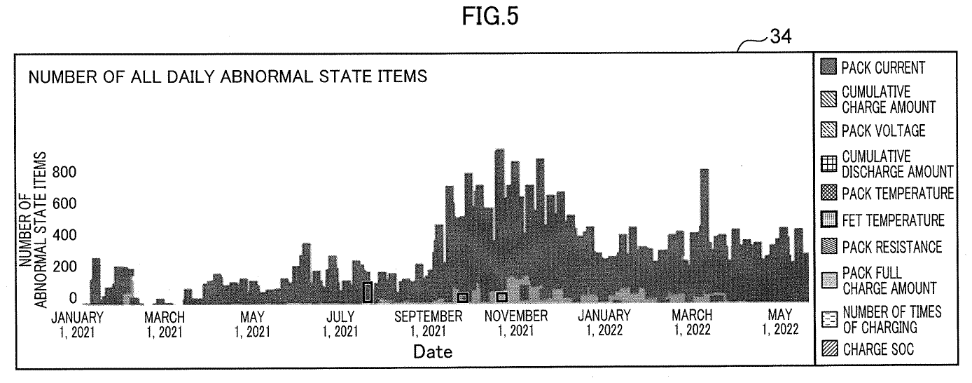

FIG. 5 is a diagram illustrating an example of an abnormal state item display screen displaying a plurality of abnormal state items of a plurality of the batteries 1 in Modification Example 1 of the present embodiment.

The display part 34 may display the abnormal state item display screen illustrated in FIG. 5. The abnormal state item display screen includes a bar graph indicating the number of abnormal state items occurring in a predetermined period. The vertical axis represents the number of abnormal state items, and the horizontal axis represents year, month, and day. The bar graphs are stacked by being color-coded in accordance with abnormal state items.

The display part 34 displays a monitored state item among a plurality of abnormal state items of a plurality of the batteries 1 in a mode different from other abnormal state items. In FIG. 5, the monitored state item is FET temperature. The display part 34 highlights the monitored state item. The display part 34 highlights the monitored state item by surrounding the periphery of the monitored state item with a frame of a predetermined color. The predetermined color is, for example, red.

Further, in Modification Example 1 of the present embodiment, the display part 34 displays a monitored state item on the lower side of a stacked bar graph. That is, the display part 34 displays the monitored state item from the origin of the vertical axis of the stacked bar graph.

By this, the number of monitored state items for each year, month, and day on the horizontal axis can be easily compared, and it is possible to support determination of an error that has occurred in a battery by the user.

Further, in Modification Example 2 of the present embodiment, the display part 34 may display a monitored state item on the upper side of a stacked bar graph.

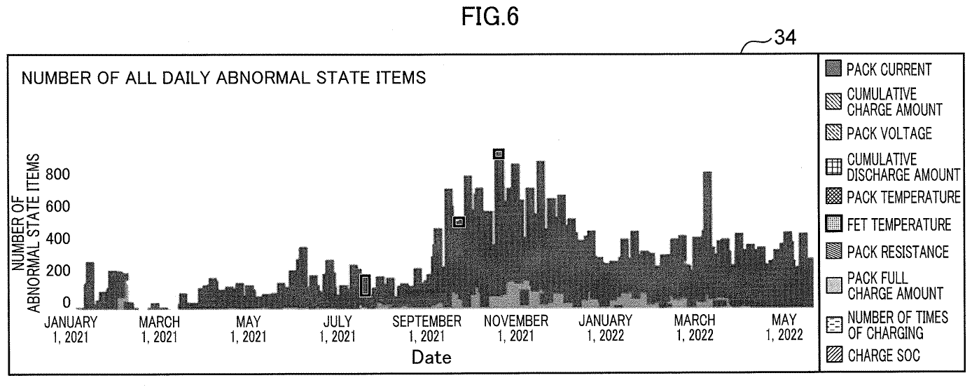

FIG. 6 is a diagram illustrating an example of an abnormal state item display screen displaying a plurality of abnormal state items of a plurality of the batteries 1 in Modification Example 2 of the present embodiment.

The display part 34 may display the abnormal state item display screen illustrated in FIG. 6. The abnormal state item display screen includes a bar graph indicating the number of abnormal state items occurring in a predetermined period. The vertical axis represents the number of abnormal state items, and the horizontal axis represents year, month, and day. The bar graphs are stacked by being color-coded in accordance with abnormal state items.

The display part 34 displays a monitored state item among a plurality of abnormal state items of a plurality of the batteries 1 in a mode different from other abnormal state items. In FIG. 6, the monitored state item is FET temperature. The display part 34 highlights the monitored state item. The display part 34 highlights the monitored state item by surrounding the periphery of the monitored state item with a frame of a predetermined color. The predetermined color is, for example, red.

Further, in Modification Example 2 of the present embodiment, the display part 34 displays a monitored state item on the upper side of a stacked bar graph. That is, the display part 34 displays the monitored state item from the maximum value side of the vertical axis of the stacked bar graph.

By this, the monitored state item is displayed without being buried in other abnormal state items, and it is possible to support determination of an error that has occurred in a battery by the user.

Note that, in the present embodiment, the display part 34 displays a plurality of abnormal state items of a plurality of batteries and displays a monitored state item among the plurality of abnormal state items in a mode different from other abnormal state items, but the present embodiment is not limited to this. In Modification Example 3 of the present embodiment, the display part 34 displays a plurality of abnormal state items of one battery, and displays a monitored state item among a plurality of abnormal state items in a mode different from other abnormal state items.

The battery management system according to Modification Example 3 of the present embodiment will be described with reference to FIG. 1. Note that in Modification Example 3 of the present embodiment, only changes will be described.

The communication part 21 of the server 2 transmits, to the information terminal 3, a plurality of abnormal state items indicating state items in which an abnormal value is detected from among a plurality of state items indicating a plurality of states of a plurality of the batteries 1.

Further, the communication part 21 receives a data request transmitted by the information terminal 3. The data request includes one abnormal state item of one battery selected by the user.

The controller 22 determines a monitored state item, which is an abnormal state item that needs to be handled, among a plurality of abnormal state items of one battery corresponding to one abnormal state item included in the data request received by the communication part 21. Note that the method of determining a monitored state item is the same as that in the above embodiment. The controller 22 sets a display mode of a monitored state item among a plurality of abnormal state items of one battery to be different from display modes of other abnormal state items.

The communication part 21 transmits, to the information terminal 3, a plurality of abnormal state items of one battery whose display modes are set by the controller 22.

The communication part 31 of the information terminal 3 receives a plurality of abnormal state items of a plurality of the batteries 1 transmitted by the server 2. That is, the communication part 31 acquires a plurality of abnormal state items indicating state items in which an abnormal value is detected from among a plurality of state items indicating a plurality of states of a plurality of the batteries 1.

The controller 32 controls the display part 34 to display a list of a plurality of abnormal state items of a plurality of the batteries 1 received by the communication part 31.

The display part 34 displays a list of a plurality of abnormal state items of a plurality of the batteries 1 received by the communication part 31. At this time, the display part 34 receives selection by the user of one abnormal state item of one battery among the plurality of abnormal state items received by the communication part 31. When selection of one abnormal state item of one battery by the user is received, the controller 32 identifies one battery from among a plurality of batteries.

The communication part 31 transmits, to the server 2, a data request for requesting a plurality of abnormal state items of one battery corresponding to the selected one abnormal state item. Further, the communication part 31 receives a plurality of abnormal state items of one battery transmitted by the server 2. That is, the communication part 31 acquires a plurality of abnormal state items indicating state items in which an abnormal value is detected from among a plurality of state items indicating a plurality of states of the one battery 1.

The controller 32 controls the display part 34 to display a list of a plurality of abnormal state items of one battery received by the communication part 31. Further, the controller 32 controls the display part 34 to display a monitored state item, which is an abnormal state item that needs to be handled among a plurality of abnormal state items of one battery, in a mode different from other abnormal state items.

The display part 34 displays a list of a plurality of abnormal state items of one battery received by the communication part 31. At this time, the display part 34 displays the plurality of abnormal state items of one battery, and displays a monitored state item among the plurality of abnormal state items in a mode different from other abnormal state items.

Next, operation of the battery management system in Modification Example 3 of the embodiment of the present disclosure will be described.

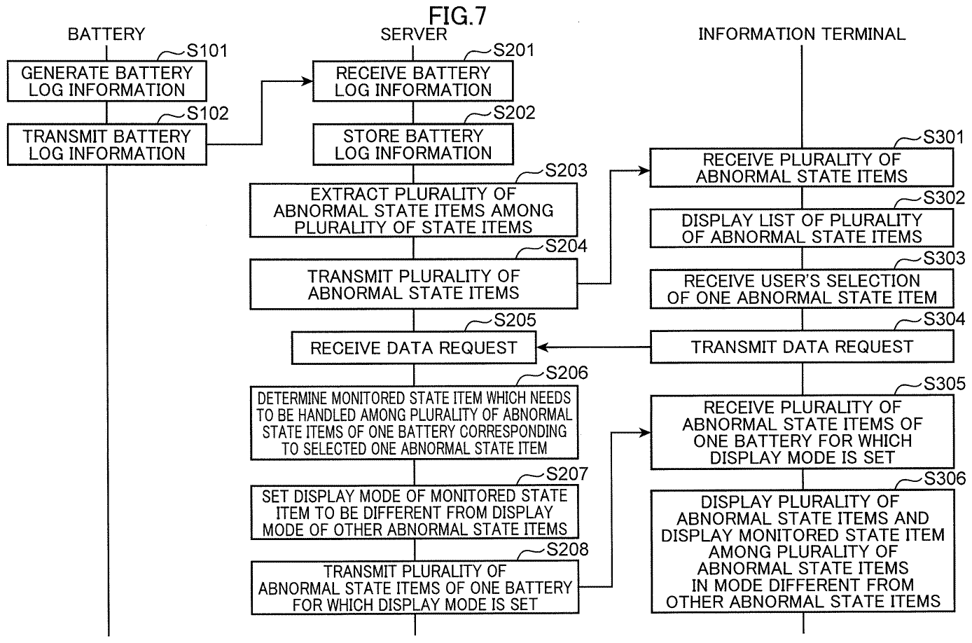

FIG. 7 is a sequence diagram for describing operation of the battery management system in Modification Example 3 of the embodiment of the present disclosure.

Processing in Steps S101 to S203 of FIG. 7 is the same as the processing in Steps S11 to S23 in FIG. 2, and thus will be omitted from description.

Next, in Step S204, the communication part 21 transmits a plurality of abnormal state items of a plurality of batteries extracted by the controller 22 to the information terminal 3. Note that each of the plurality of abnormal state items is associated with which battery the abnormal state item pertains to.

Next, in Step S301, the communication part 31 of the information terminal 3 receives a plurality of abnormal state items transmitted by the server 2.

Next, in Step S302, the display part 34 displays a list of the plurality of abnormal state items received by the communication part 31.

Next, in Step S303, the display part 34 receives selection by the user of one abnormal state item of one battery among the plurality of abnormal state items received by the communication part 31.

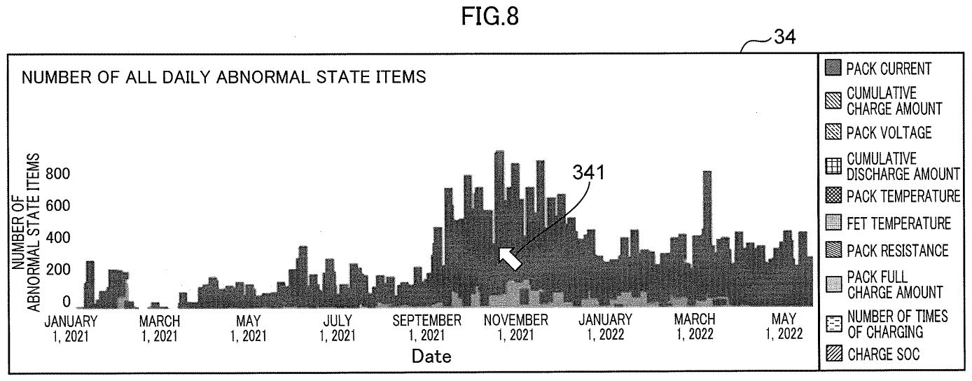

FIG. 8 is a diagram illustrating an example of an abnormal state item display screen displaying a list of a plurality of abnormal state items in Modification Example 3 of the present embodiment.

The display part 34 displays the abnormal state item display screen illustrated in FIG. 8. The abnormal state item display screen includes a bar graph indicating the number of abnormal state items occurring in a predetermined period. The vertical axis represents the number of abnormal state items, and the horizontal axis represents year, month, and day. The bar graphs are stacked by being color-coded in accordance with abnormal state items. The displayed abnormal state items are the same as those in FIG. 4.

The stacked bar graphs are selectable. For example, the user moves a pointer 341 on a screen by operating a mouse (not illustrated) and clicks on a desired bar graph. Alternatively, for example, in a case where the display part 34 is a touch panel, the user touches a desired bar graph. One abnormal state item of one battery is selected by selecting one point of a desired bar graph.

Returning to FIG. 7, next, in Step S304, the communication part 31 transmits, to the server 2, a data request for requesting a plurality of abnormal state items of one battery corresponding to the selected one abnormal state item. The data request includes information (battery ID) indicating one battery selected by the user and information indicating one abnormal state item.

Next, in Step S205, the communication part 21 of the server 2 receives the data request transmitted by the information terminal 3.

Next, in Step S206, the controller 22 determines a monitored state item, which is an abnormal state item that needs to be handled, among a plurality of abnormal state items of one battery corresponding to the selected one abnormal state item included in the data request received by the communication part 21.

Next, in Step S207, the controller 22 sets a display mode of the monitored state item among a plurality of abnormal state items of one battery to be different from display modes of other abnormal state items.

Next, in Step S208, the communication part 21 transmits, to the information terminal 3, a plurality of abnormal state items of one battery whose display modes are set by the controller 22.

Next, in Step S305, the communication part 31 of the information terminal 3 receives the plurality of abnormal state items of one battery whose display modes are set, the plurality of abnormal state items being transmitted by the server 2.

Next, in Step S306, the display part 34 displays the plurality of abnormal state items of one battery received by the communication part 31, and displays the monitored state item among the plurality of abnormal state items of one battery in a mode different from other abnormal state items. Note that the abnormal state item display screen displaying the plurality of abnormal state items of one battery is the same as that in FIG. 4. However, in FIG. 4, a plurality of abnormal state items of all of a plurality of batteries are displayed, but in Modification Example 3 of the present embodiment, a plurality of abnormal state items of one battery are displayed.

As described above, in Modification Example 3 of the present embodiment, a plurality of abnormal state items of one battery are displayed instead of a plurality of abnormal state items of a plurality of batteries, and therefore, the number of a plurality of abnormal state items to be displayed can be suppressed, and it is possible to support determination of an error that has occurred in a battery by the user.

In Modification Example 3 of the present embodiment, one battery corresponding to one abnormal state item is identified by selecting an abnormal state item from a plurality of displayed abnormal state items of a plurality of batteries, but the present disclosure is not particularly limited to this, and one battery may be identified by selecting a battery ID for identifying one battery. For example, the display part 34 may display a pull-down menu listing battery IDs of a plurality of batteries, and receive selection of a battery ID by an administrator.

Further, the display part 34 may display battery IDs of a plurality of batteries on the right side of an abnormal state item display screen and receive selection of a battery ID by an administrator. In this case, the administrator selects one desired battery ID from the plurality of displayed battery IDs.

Further, in Modification Example 4 of the present embodiment, abnormality degree indicating degree of abnormality may be associated with each of a plurality of abnormal state items. Then, the controller 22 may determine an abnormal state item having maximum abnormality degree among the plurality of abnormal state items as a monitored state item.

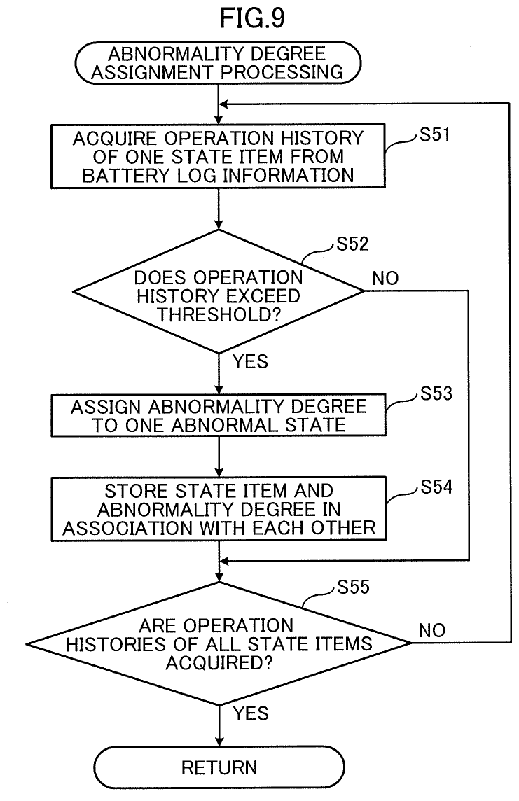

FIG. 9 is a flowchart for describing abnormality degree assignment processing of the server 2 in Modification Example 4 of the embodiment of the present disclosure. The abnormality degree assignment processing may be performed between Step S22 and Step S23 in FIG. 2, or may be performed between Step S23 and Step S24 in FIG. 2. Further, the abnormality degree assignment processing may be performed between Step S202 and Step S203 in FIG. 7, between Step S203 and Step S204 in FIG. 7, or between Step S204 and Step S205 in FIG. 7.

First, in Step S51, the controller 22 acquires an operation history of one state item from the battery log information stored in the memory 23. At this time, the controller 22 acquires an operation history of one state item for a predetermined period.

Next, in Step S52, the controller 22 determines whether the acquired operation history exceeds a threshold. Here, in a case where it is determined that the operation history does not exceed the threshold (NO in Step S52), the processing proceeds to Step S55.

On the other hand, in a case where it is determined that the operation history exceeds the threshold (YES in Step S52), in Step S53, the controller 22 assigns abnormality degree to one state item.

Note that an assignment method of abnormality degree may be different for every state item. Here, the assignment method of abnormality degree will be described.

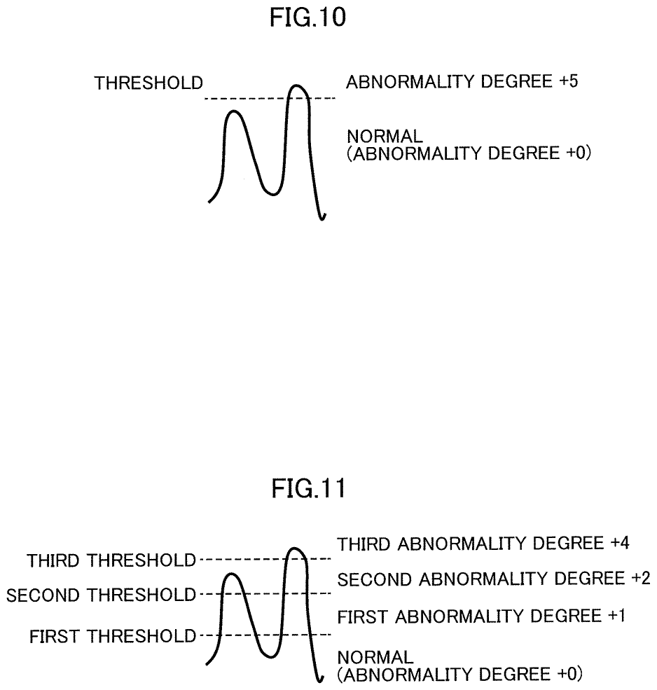

FIG. 10 is a schematic diagram for describing a first assignment method of abnormality degree in Modification Example 4 of the present embodiment.

In the first assignment method, it is important whether or not an operation history of a state item exceeds a threshold. In a case where it is determined that the operation history exceeds the threshold, the controller 22 assigns a predetermined abnormality degree to the state item. As illustrated in FIG. 10, in a case where a peak value of an operation history indicated by a solid line exceeds a threshold indicated by a broken line, the controller 22 assigns a predetermined abnormality degree (for example, +5) to a state item. On the other hand, in a case where the peak value of the operation history does not exceed the threshold, the controller 22 does not assign the predetermined abnormality degree to the state item.

Note that in a case where a peak value of an operation history does not exceed the threshold, the controller 22 may assign an abnormality degree of 0 to a state item. Further, in a case where abnormality degree of 0 is assigned to a state item in advance, and a peak value of an operation history exceeds a threshold, the controller 22 may assign a predetermined abnormality degree (for example, +5) to the state item. Further, the threshold may be set in advance by the user, or may be set based on an average value or a variance value of an operation history of a state item.

FIG. 11 is a schematic diagram for describing a second assignment method of abnormality degree in Modification Example 4 of the present embodiment.

In the second assignment method, it is important how much an operation history of a state item exceeds a threshold. In a case where it is determined that an operation history exceeds a threshold, the controller 22 assigns abnormality degree corresponding to degree of exceeding the threshold to a state item. As illustrated in FIG. 11, the controller 22 determines whether or not a peak value of an operation history indicated by a solid line exceeds the lowest first threshold indicated by a broken line. In a case where the peak value of the operation history exceeds the first threshold, the controller 22 determines whether or not the peak value of the operation history exceeds a second threshold higher than the first threshold. Here, in a case where the peak value of the operation history does not exceed the second threshold, the controller 22 assigns a first abnormality degree (for example, +1) to a state item. On the other hand, in a case where the peak value of the operation history exceeds the second threshold, the controller 22 determines whether or not the peak value of the operation history exceeds a third threshold higher than the second threshold. Here, in a case where the peak value of the operation history does not exceed the third threshold, the controller 22 assigns a second abnormality degree (for example, +2) higher than the first abnormality degree to the state item. On the other hand, in a case where the peak value of the operation history exceeds the third threshold, the controller 22 assigns a third abnormality degree (for example, +4) higher than the second abnormality degree to the state item. Note that in a case where the peak value of the operation history does not exceed the first threshold, the controller 22 does not assign the predetermined abnormality degree to the state item.

Note that in a case where the peak value of the operation history does not exceed the first threshold, the controller 22 may assign the abnormality degree of 0 to the state item. Further, in a case where the abnormality degree of 0 is assigned to the state item in advance and the peak value of the operation history exceeds the first threshold, the second threshold, or the third threshold, the controller 22 may assign the first abnormality degree, the second abnormality degree, or the third abnormality degree to the state item. Further, the first threshold, the second threshold, and the third threshold may be set in advance by the user, or may be set based on the average value or the variance value of the operation history of the state item.

Referring to FIG. 9 again, next, in Step S54, the controller 22 stores the state item and the abnormality degree in the memory 23 in association with each other.

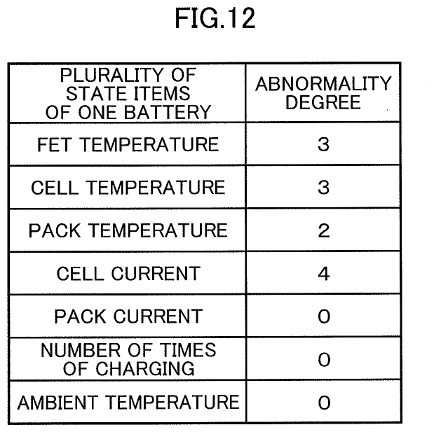

FIG. 12 is a diagram for describing the abnormality degree assigned to a plurality of state items of one battery in Modification Example 4 of the present embodiment.

As illustrated in FIG. 12, abnormality degree is assigned to a plurality of state items of one battery. For example, an abnormality degree “3” is assigned to the FET temperature at which an abnormal value is detected, an abnormality degree “3” is assigned to the cell temperature at which an abnormal value is detected, an abnormality degree “2” is assigned to the pack temperature at which an abnormal value is detected, and an abnormality degree “4” is assigned to the cell current at which an abnormal value is detected. Further, for example, pack current, the number of times of charging, and ambient temperature at which no abnormal value is detected are assigned the abnormality degree “0”.

Referring to FIG. 9 again, next, in Step S55, the controller 22 determines whether the operation histories of all the state items included in the battery log information have been acquired. Here, in a case where it is determined that the operation histories of all the state items have been acquired (YES in Step S55), the abnormality degree assignment processing ends. On the other hand, in a case where it is determined that the operation histories of all the state items have not been acquired (NO in Step S55), the processing returns to Step S51, and the controller 22 acquires the operation histories of other state items that have not yet been acquired from the battery log information stored in the memory 23.

Abnormality degree of each of a plurality of abnormal state items is determined based on degree to which an operation history of each of the plurality of abnormal state items exceeds a threshold. The controller 22 may determine an abnormal state item having the maximum abnormal degree as a monitored state item with reference to abnormal degree associated with each of a plurality of abnormal state items.

Further, in Modification Example 4 of the present embodiment, the controller 22 may determine at least one abnormal state item having an abnormality degree equal to or more than a threshold among a plurality of abnormal state items as at least one monitored state item. In this case, a plurality of abnormal state items may be displayed, and a plurality of monitored state items among the plurality of abnormal state items may be displayed in a mode different from other abnormal state items. Further, only a predetermined number of monitored state items among the plurality of determined monitored state items may be displayed in a mode different from other abnormal state items. For example, even if three monitored state items are determined, only two monitored state items may be displayed in a manner different from the other abnormal state item. The controller 22 may randomly determine a predetermined number of monitored state items to be displayed among the plurality of determined monitored state items.

Furthermore, in Modification Example 5 of the present embodiment, the controller 22 may count the number of occurrences of each of a plurality of abnormal state items in a first predetermined period. Then, the controller 22 may determine abnormality degree of each of the plurality of abnormal state items based on degree to which the number of occurrences exceeds a threshold. The controller 22 may assign abnormality degree in a case where an operation history of each of a plurality of state items exceeds a threshold, and count the number of times the operation history of each of the plurality of abnormal state items exceeds a threshold as the number of abnormality occurrences. Then, the controller 22 may determine whether the number of abnormality occurrences exceeds a threshold. In a case where the number of abnormality occurrences exceeds a threshold, the controller 22 may add a predetermined value to abnormality degree. Further, in a case where the number of abnormality occurrences does not exceed the threshold, the controller 22 does not need to add the predetermined value to the abnormality degree.

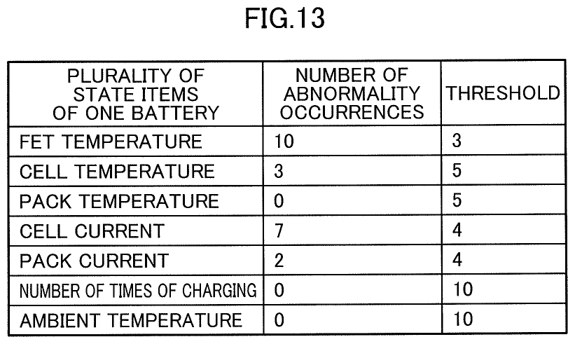

FIG. 13 is a diagram illustrating an example of a table in which a plurality of state items of one battery, the number of abnormality occurrences, and a threshold are associated with each other in Modification Example 5 of the present embodiment.

As illustrated in FIG. 13, the memory 23 may store a table in which a plurality of state items of one battery, the number of abnormality occurrences, and a threshold are associated with each other. The controller 22 may count the number of times an operation history of each of a plurality of abnormal state items in a first predetermined period exceeds a threshold as the number of abnormality occurrences, and store the counted number of abnormality occurrences in the table. For example, the number of abnormality occurrences of FET temperature is 10, and the number of abnormality occurrences of cell temperature is 3. Further, for example, a threshold for the number of abnormality occurrences of FET temperature is 3 and a threshold for the number of abnormality occurrences of cell temperature is 5. The threshold may be different for each state item.

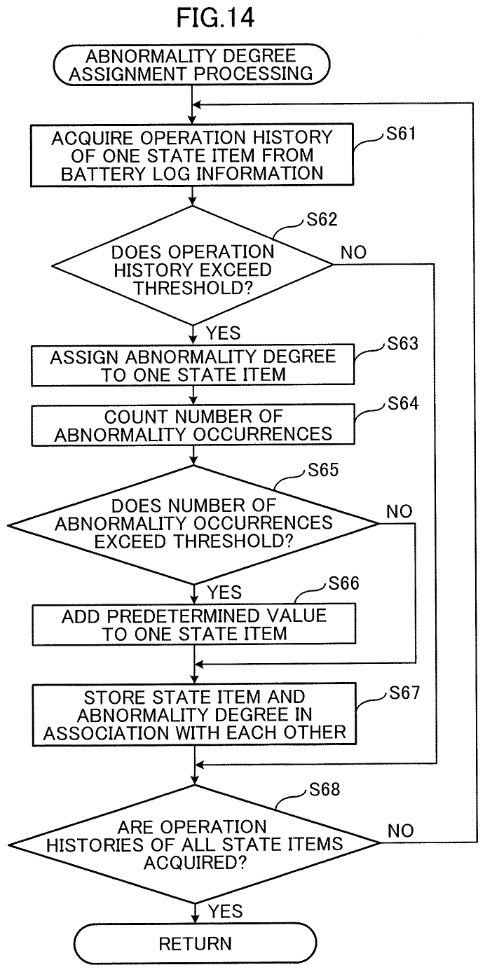

FIG. 14 is a flowchart for describing abnormality degree assignment processing of the server 2 in Modification Example 5 of the embodiment of the present disclosure. The abnormality degree assignment processing may be performed between Step S22 and Step S23 in FIG. 2, or may be performed between Step S23 and Step S24 in FIG. 2. Further, the abnormality degree assignment processing may be performed between Step S202 and Step S203 in FIG. 7, between Step S203 and Step S204 in FIG. 7, or between Step S204 and Step S205 in FIG. 7.

Processing in Step S61 and Step S62 is the same as the processing in Step S51 and Step S52 in FIG. 9, and will be omitted from description.

In a case where it is determined that the operation history exceeds the threshold (YES in Step S62), in Step S63, the controller 22 assigns abnormality degree to one state item. Note that a value of the abnormality degree to be assigned is determined in advance according to a state item. Further, even if an operation history exceeds a threshold a plurality of times in the first predetermined period, the controller 22 assigns only one abnormality degree to one state item. Further, in a case where an operation history exceeds the threshold a plurality of times in the first predetermined period, the controller 22 may assign a value obtained by multiplying the number of times the operation history exceeds the threshold by abnormality degree to one state item. The first predetermined period is 1 day, for example.

Next, in Step S64, the controller 22 counts the number of times the operation history of one state item (abnormal state item) in the first predetermined period exceeds the threshold as the number of abnormality occurrences.

Next, in Step S65, the controller 22 determines whether or not the number of abnormality occurrences exceeds the threshold. Here, in a case where it is determined that the number of abnormality occurrences exceeds the threshold (YES in Step S65), in Step S66, the controller 22 adds a predetermined value to the abnormality degree of one state item.

Note that, in Modification Example 5 of the present embodiment, in a case where it is determined that the number of abnormality occurrences exceeds the threshold, the controller 22 adds a predetermined value to the abnormality degree of one state item, but the present disclosure is not particularly limited to this. In a case where it is determined that the number of abnormality occurrences exceeds the threshold, the controller 22 may multiply abnormality degree of one state item by a predetermined coefficient to increase the abnormality degree.

Further, the controller 22 may change a predetermined value according to magnitude of a difference between the number of abnormality occurrences and the threshold. The controller 22 may increase the predetermined value as a difference between the number of abnormality occurrences and the threshold increases. For example, the controller 22 may add the first predetermined value to abnormality degree in a case where a difference between the number of abnormality occurrences and the threshold is equal to or less than a predetermined number of times, and may add a second predetermined value larger than the first predetermined value to the abnormality degree in a case where the difference between the number of abnormality occurrences and the threshold is larger than the predetermined number of times. Further, the controller 22 may increase the predetermined value in proportion to magnitude of a difference between the number of abnormality occurrences and the threshold. In this case, an upper limit value may be set to the predetermined value.

On the other hand, in a case where it is determined that the number of abnormality occurrences does not exceed the threshold (NO in Step S65), the processing proceeds to Step S67. In this case, the controller 22 does not add the predetermined value to abnormality degree of one state item.

Next, in Step S67, the controller 22 stores the state item and the abnormality degree in the memory 23 in association with each other.

Processing in Step S68 is the same as the processing in Step S55 illustrated in FIG. 9, and thus will be omitted from description.

Note that, in a case where it is determined that the number of abnormality occurrences does not exceed the threshold, the controller 22 may reset the abnormality degree of one state item to 0. Further, in a case where it is determined that the number of abnormality occurrences does not exceed the threshold, the controller 22 may determine whether or not the number of abnormality occurrences exceeds a lower limit value smaller than the threshold. In a case where it is determined that the number of abnormality occurrences exceeds the lower limit value, the controller 22 does not add the predetermined value to the abnormality degree of one state item. Further, in a case where it is determined that the number of abnormality occurrences does not exceed the lower limit value, the controller 22 may reset the abnormality degree of one state item to zero.

In Modification Example 5 of the above embodiment, in a case where an operation history exceeds the threshold, abnormality degree is assigned to one state item, and it is determined whether the number of abnormality occurrences exceeds the threshold. Then, in a case where the number of abnormality occurrences exceeds the threshold, a predetermined value is added to the abnormality degree of one state item. On the other hand, in Modification Example 6 of the embodiment, in a case where an operation history exceeds the threshold, abnormality degree is not assigned to one state item, and it is determined whether the number of abnormality occurrences exceeds the threshold. Then, in a case where the number of abnormality occurrences exceeds the threshold, abnormality degree is assigned to one state item.

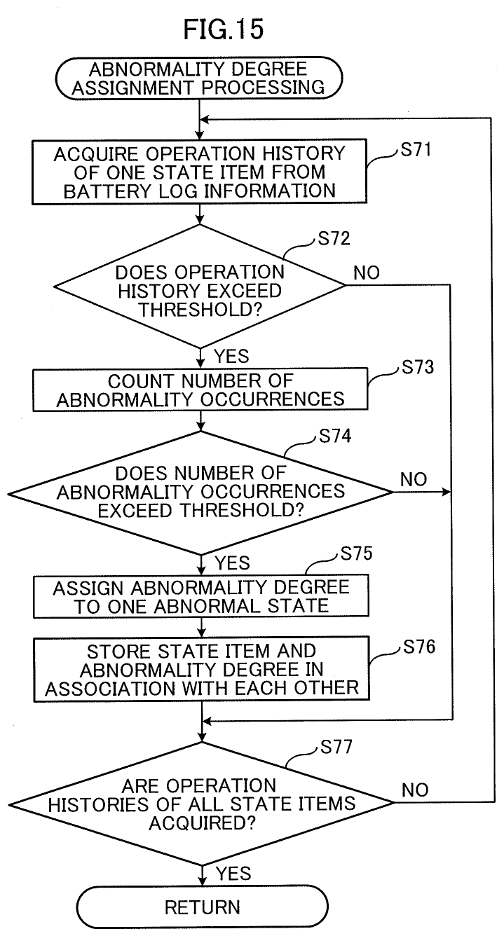

FIG. 15 is a flowchart for describing abnormality degree assignment processing of the server 2 in Modification Example 6 of the embodiment of the present disclosure. The abnormality degree assignment processing may be performed between Step S22 and Step S23 in FIG. 2, or may be performed between Step S23 and Step S24 in FIG. 2. Further, the abnormality degree assignment processing may be performed between Step S202 and Step S203 in FIG. 7, between Step S203 and Step S204 in FIG. 7, or between Step S204 and Step S205 in FIG. 7.

Processing in Step S71 and Step S72 is the same as the processing in Step S51 and Step S52 in FIG. 9, and will be omitted from description.

In a case where it is determined that the operation history exceeds the threshold (YES in Step S72), in Step S73, the controller 22 counts the number of times the operation history of one state item (abnormal state item) in the first predetermined period exceeds the threshold as the number of abnormality occurrences.

Next, in Step S74, the controller 22 determines whether or not the number of abnormality occurrences exceeds the threshold. Here, in a case where it is determined that the number of abnormality occurrences exceeds the threshold (YES in Step S74), in Step S75, the controller 22 assigns abnormality degree to one state item. Note that a value of the abnormality degree to be assigned is determined in advance according to a state item.

Further, the controller 22 may change abnormality degree according to magnitude of a difference between the number of abnormality occurrences and the threshold. The controller 22 may increase a value of abnormality degree as a difference between the number of abnormality occurrences and the threshold increases. For example, in a case where a difference between the number of abnormality occurrences and the threshold is equal to or less than a predetermined number of times, the controller 22 may assign a first predetermined value to one state item as abnormality degree, and in a case where the difference between the number of abnormality occurrences and the threshold is larger than the predetermined number of times, the controller 22 may assign a second predetermined value larger than the first predetermined value to one state item as abnormality degree. Further, the controller 22 may increase a value of abnormality degree in proportion to magnitude of a difference between the number of abnormality occurrences and the threshold. In this case, an upper limit value may be set for a value of abnormality degree.

Next, in Step S76, the controller 22 stores the state item and the abnormality degree in the memory 23 in association with each other.

On the other hand, in a case where it is determined that the number of abnormality occurrences does not exceed the threshold (NO in Step S74), the processing proceeds to Step S77. In this case, the controller 22 does not assign abnormality degree to one state item.

Processing in Step S77 is the same as the processing in Step S55 illustrated in FIG. 9, and thus will be omitted from description.

Further, in Modification Examples 5 and 6 of the present embodiment, a threshold for the number of abnormality occurrences may be set for each of a plurality of periods. That is, one year may be divided into a plurality of periods. The controller 22 may select one threshold from among a plurality of thresholds different for each of a plurality of periods according to which of the plurality of periods the first predetermined period is included.

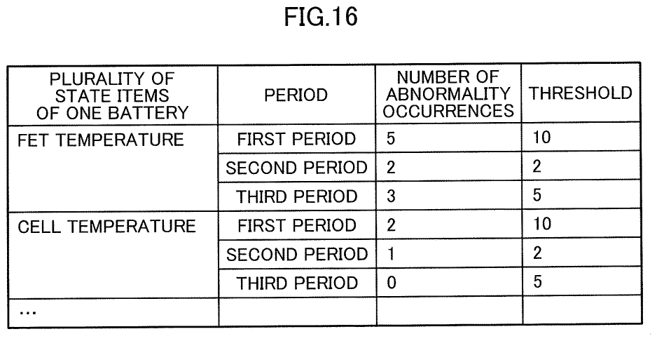

FIG. 16 is a diagram illustrating an example of a table in which a plurality of state items of one battery, a plurality of periods, the number of abnormality occurrences, and a threshold are associated with each other in Modification Example 5 and Modification Example 6 of the present embodiment.

As illustrated in FIG. 16, the memory 23 may store a table in which a plurality of state items of one battery, a plurality of periods, the number of abnormality occurrences, and a threshold are associated with each other. A threshold for the number of abnormality occurrences of each state item may be different for each of a plurality of periods. The plurality of periods includes a first period, a second period, and a third period. For example, the first period is a summer period from June to August, the second period is a winter period from December to February, and the third period is a spring period from March to May and an autumn period from September to November.

The controller 22 may determine whether a period in which an operation history is acquired is included in any of the first period, the second period, and the third period, and select a threshold corresponding to the determination result.

In FIG. 16, sensitivity of abnormality degree for each season is changed by making a threshold different for each season. Batteries are affected by air temperature. For example, when the number of abnormality occurrences of FET temperature increases during a winter period in which air temperature is low, it is estimated that there is a high possibility that temperature abnormality occurs in a battery.

Note that although a threshold is set for each season, an administrator may set each of a plurality of periods.

Further, in Modification Example 7 of the present embodiment, abnormality degree of each of a plurality of abnormal state items may be determined based on time during which an operation history of each of the plurality of abnormal state items continuously exceeds a threshold.

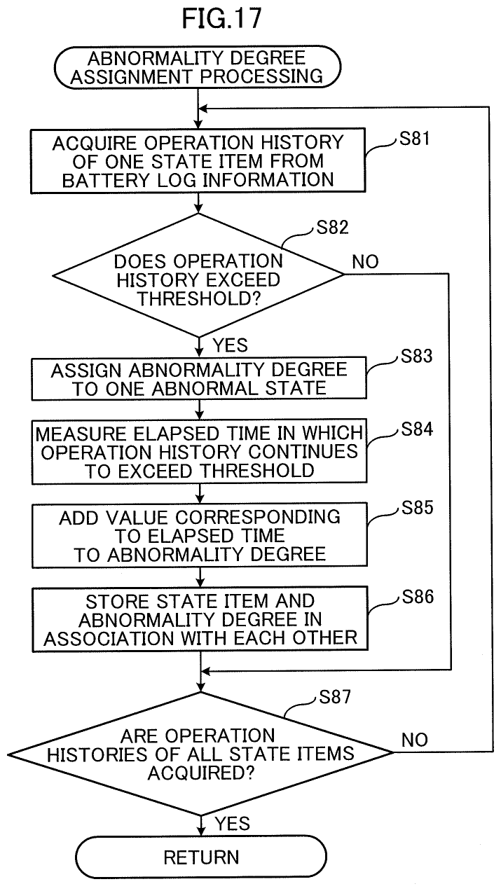

FIG. 17 is a flowchart for describing abnormality degree assignment processing of the server 2 in Modification Example 7 of the embodiment of the present disclosure. The abnormality degree assignment processing may be performed between Step S22 and Step S23 in FIG. 2, or may be performed between Step S23 and Step S24 in FIG. 2. Further, the abnormality degree assignment processing may be performed between Step S202 and Step S203 in FIG. 7, between Step S203 and Step S204 in FIG. 7, or between Step S204 and Step S205 in FIG. 7.

Processing in Steps S81 to S83 is the same as the processing in Steps S51 to S53 in FIG. 9, and thus will be omitted from description.

Next, in Step S84, the controller 22 measures elapsed time during which an operation history continuously exceeds a threshold.

Next, in Step S85, the controller 22 adds a value corresponding to elapsed time to abnormality degree of one state item.

Here, elapsed time in Modification Example 7 of the present embodiment will be described.

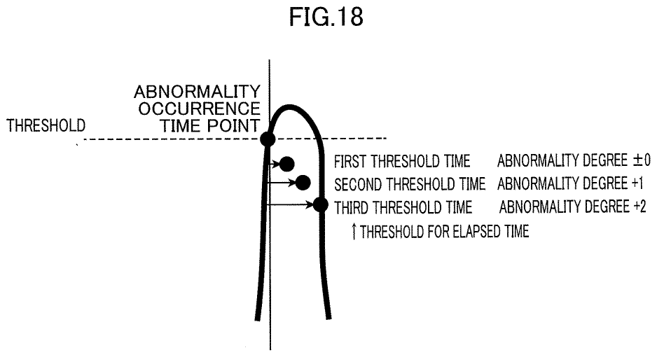

FIG. 18 is a diagram for describing elapsed time in Modification Example 7 of the present embodiment. FIG. 18 illustrates a peak portion of an operation history of FIG. 10.

As illustrated in FIG. 18, the controller 22 measures elapsed time in which an operation history continuously exceeds a threshold from a time point at which an operation history exceeds the threshold, that is, an abnormality occurrence time point.

In a case where elapsed time is equal to or less than first threshold time, the controller 22 maintains current abnormality degree and does not add a value to the abnormality degree. For example, the first threshold time is time during which an operation history instantaneously exceeds a threshold, and is minute time that can be ignored.

Further, in a case where elapsed time exceeds second threshold time longer than the first threshold time, the controller 22 adds a first predetermined value to abnormality degree. For example, the second threshold time is time that does not cause a problem even if an operation history continuously exceeds the threshold. The first predetermined value is, for example, 1.

Further, in a case where elapsed time exceeds third threshold time longer than the second threshold time, the controller 22 adds a second predetermined value to abnormality degree. For example, the third threshold time is time that causes a problem in a case where an operation history continuously exceeds the threshold. The second predetermined value is, for example, 2.

Note that the controller 22 may multiply abnormality degree by a first coefficient in a case where elapsed time is equal to or less than the first threshold time. The first coefficient is, for example, 0.5. The first coefficient may be a value smaller than 1. Further, the controller 22 may multiply abnormality degree by a second coefficient in a case where elapsed time exceeds the second threshold time longer than the first threshold time. The second coefficient is, for example, 1. Further, the controller 22 may multiply abnormality degree by a third coefficient in a case where elapsed time exceeds the third threshold time longer than the second threshold time. The third coefficient is, for example, 1.5.

Further, the controller 22 may reset abnormality degree to zero in a case where elapsed time is equal to or less than the first threshold time.

Referring to FIG. 17 again, next, in Step S86, the controller 22 stores the state item and the abnormality degree in the memory 23 in association with each other.

Processing in Step S87 is the same as the processing in Step S55 illustrated in FIG. 9, and thus will be omitted from description.

Further, in Modification Example 8 of the present embodiment, abnormality degree of each of a plurality of abnormal state items may be determined based on the number of days during which an operation history of each of the plurality of abnormal state items continuously exceeds a threshold.

In this case, in Step S84 of FIG. 17, the controller 22 may measure the number of abnormality occurrence continuation days during which an operation history continuously exceeds the threshold. At this time, in a case where an operation history exceeds the threshold even once a day, the controller 22 adds 1 to the number of abnormality occurrence continuation days of one state item. Further, in a case where an operation history does not exceed the threshold even once a day, the controller 22 resets the number of abnormality occurrence continuation days of one state item to zero. Then, in Step S85, the controller 22 may add a value corresponding to the number of abnormality occurrence continuation days to abnormality degree of one state item.

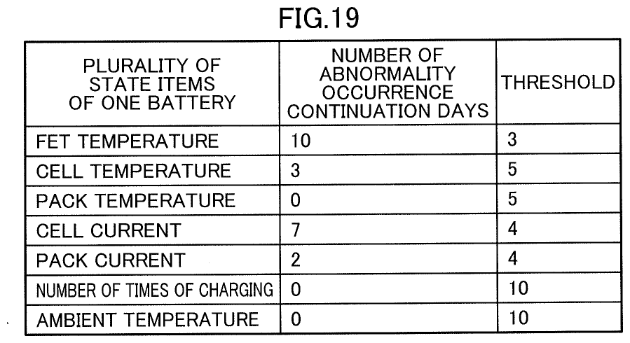

FIG. 19 is a diagram illustrating an example of a table in which a plurality of state items of one battery, the number of abnormality occurrence continuation days, and a threshold are associated with each other in Modification Example 8 of the present embodiment.

As illustrated in FIG. 19, the memory 23 may store a table in which a plurality of state items of one battery, the number of abnormality occurrence continuation days, and a threshold are associated with each other. The controller 22 may count the number of days during which an operation history of each of a plurality of abnormal state items in a predetermined period continuously exceeds the threshold as the number of abnormality occurrence continuation days, and store the counted number of abnormality occurrence continuation days in the table. For example, the number of abnormality occurrence continuation days for FET temperature is 10, and the number of abnormality occurrence continuation days for cell temperature is 3. Further, for example, a threshold for the number of abnormality occurrence continuation days for FET temperature is 3, and a threshold for the number of abnormality occurrence continuation days for cell temperature is 5. The threshold may be different for each state item.

The controller 22 may determine whether or not the number of abnormality occurrence continuation days exceeds the threshold. In a case where the number of abnormality occurrence continuation days exceeds the threshold, the controller 22 may add a predetermined value to abnormality degree. Further, in a case where the number of abnormality occurrence continuation days does not exceed the threshold, the controller 22 does not need to add a predetermined value to abnormality degree, and may add zero to abnormality degree.

Note that, in a case where it is determined that the number of abnormality occurrence continuation days exceeds the threshold, the controller 22 may multiply abnormality degree of one state item by a predetermined coefficient to increase the abnormality degree.

Furthermore, the controller 22 may change the predetermined value according to magnitude of a difference between the number of abnormality occurrence continuation days and the threshold. The controller 22 may increase the predetermined value as a difference between the number of abnormality occurrence continuation days and the threshold increases. For example, the controller 22 may add a first predetermined value to abnormality degree in a case where a difference between the number of abnormality occurrence continuation days and the threshold is equal to or less than a predetermined number of days, and may add a second predetermined value larger than the first predetermined value to the abnormality degree in a case where the difference between the number of abnormality occurrence continuation days and the threshold is larger than the predetermined number of days. Further, the controller 22 may increase the predetermined value in proportion to magnitude of a difference between the number of abnormality occurrence continuation days and the threshold. In this case, an upper limit value may be set to the predetermined value.

Further, in Modification Example 8 of the present embodiment, a threshold for one state item is not limited to one, and the number of abnormality occurrence continuation days may be compared with a plurality of thresholds.

In a case where the number of abnormality occurrence continuation days is equal to or less than a first threshold number of days, the controller 22 maintains current abnormality degree and does not add a value to the abnormality degree. For example, the first threshold number of days is the number of days during which an operation history accidentally exceeds the threshold, and is a small number of days that can be ignored.

Further, in a case where the number of abnormality occurrence continuation days exceeds a second threshold number of days more than the first threshold number of days, the controller 22 adds the first predetermined value to abnormality degree. For example, the second threshold number of days is the number of days that does not cause a problem even if an operation history continuously exceeds the threshold. The first predetermined value is, for example, 1.

Further, in a case where the number of abnormality occurrence continuation days exceeds a third threshold number of days more than the second threshold number of days, the controller 22 adds the second predetermined value to abnormality degree. For example, the third threshold number of days is the number of days that causes a problem when an operation history continuously exceeds the threshold. The second predetermined value is, for example, 2.

Note that the controller 22 may multiply abnormality degree by a first coefficient in a case where the number of abnormality occurrence continuation days is equal to or less than the first threshold number of days. The first coefficient is, for example, 0.5. The first coefficient may be a value smaller than 1. Further, the controller 22 may multiply abnormality degree by a second coefficient in a case where the number of abnormality occurrence continuation days exceeds the second threshold number of days longer than the first threshold number of days. The second coefficient is, for example, 1. Further, the controller 22 may multiply abnormality degree by a third coefficient in a case where the number of abnormality occurrence continuation days exceeds the third threshold number of days longer than the second threshold number of days. The third coefficient is, for example, 1.5.

Further, in a case where the number of abnormality occurrence continuation days is equal to or less than the first threshold number of days, the controller 22 may reset abnormality degree to zero.

Further, in Modification Example 9 of the present embodiment, the number of occurrences of a plurality of abnormal state items (the number of abnormality occurrences) in a second predetermined period longer than the first predetermined period may be counted, and abnormality degree of each of the plurality of abnormal state items may be decreased in a case where the number of abnormality occurrences exceeds a threshold, and may be increased in a case where the number of abnormality occurrences does not exceed the threshold. In a case where the number of abnormality occurrences exceeds the threshold, that is, in a case where an abnormality occurrence frequency is high, abnormality degree of an abnormal state item is reduced, so that the abnormal state item is less likely to be determined as a monitored state item. In a case where the number of abnormality occurrences does not exceed the threshold, that is, in a case where an abnormality occurrence frequency is low, abnormality degree of an abnormal state item is increased, so that the abnormal state item is likely to be determined as a monitored state item.

By this, an abnormal state item having a lower occurrence frequency than an abnormal state item having a higher occurrence frequency can be displayed as a monitored state item.

In Modification Example 9 of the present embodiment, the controller 22 may assign abnormality degree in a case where an operation history of each of a plurality of state items exceeds a threshold, and count the number of times the operation history of each of the plurality of abnormal state items exceeds a threshold as the number of abnormality occurrences. Then, the controller 22 may determine whether the number of abnormality occurrences exceeds a threshold. In a case where the number of abnormality occurrences exceeds a threshold, the controller 22 may subtract a predetermined value from abnormality degree. Further, in a case where the number of abnormality occurrences does not exceed the threshold, the controller 22 may add a predetermined value to the abnormality degree.

Also in Modification Example 9 of the present embodiment, as illustrated in FIG. 13, the memory 23 may store a table in which a plurality of state items of one battery, the number of abnormality occurrences, and a threshold are associated with each other. The controller 22 may count the number of times an operation history of each of a plurality of abnormal state items in the second predetermined period exceeds a threshold as the number of abnormality occurrences, and store the counted number of abnormality occurrences in the table.

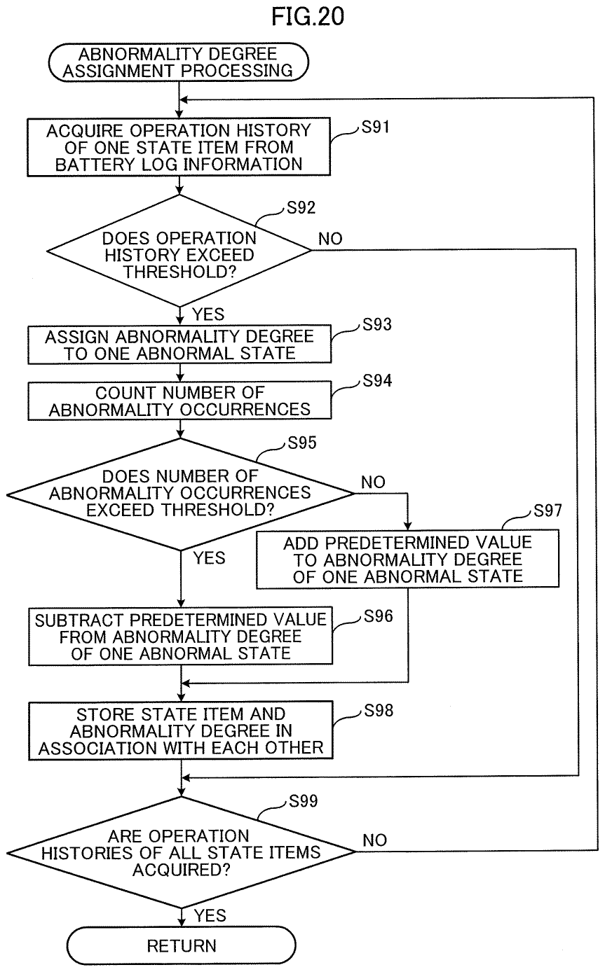

FIG. 20 is a flowchart for describing abnormality degree assignment processing of the server 2 in Modification Example 9 of the embodiment of the present disclosure. The abnormality degree assignment processing may be performed between Step S22 and Step S23 in FIG. 2, or may be performed between Step S23 and Step S24 in FIG. 2. Further, the abnormality degree assignment processing may be performed between Step S202 and Step S203 in FIG. 7, between Step S203 and Step S204 in FIG. 7, or between Step S204 and Step S205 in FIG. 7.

Processing in Steps S91 to S95 is the same as the processing in Steps S61 to S65 in FIG. 14, and thus will be omitted from description.

In a case where it is determined that the number of abnormality occurrences exceeds the threshold (YES in Step S95), in Step S96, the controller 22 subtracts a predetermined value from the abnormality degree of one state item.

Note that, in Modification Example 9 of the present embodiment, in a case where it is determined that the number of abnormality occurrences exceeds the threshold, the controller 22 subtracts a predetermined value from the abnormality degree of one state item, but the present disclosure is not particularly limited to this. In a case where it is determined that the number of abnormality occurrences exceeds the threshold, the controller 22 may multiply abnormality degree of one state item by a predetermined coefficient to decrease the abnormality degree.

On the other hand, in a case where it is determined that the number of abnormality occurrences does not exceed the threshold (NO in Step S95), in Step S97, the controller 22 adds a predetermined value to the abnormality degree of one state item.

Note that, in Modification Example 9 of the present embodiment, in a case where it is determined that the number of abnormality occurrences does not exceed the threshold, the controller 22 adds a predetermined value to the abnormality degree of one state item, but the present disclosure is not particularly limited to this. In a case where it is determined that the number of abnormality occurrences does not exceed the threshold, the controller 22 may multiply abnormality degree of one state item by a predetermined coefficient to increase the abnormality degree.

Further, the predetermined value subtracted from abnormality degree in a case where it is determined that the number of abnormality occurrences exceeds the threshold and the predetermined value added to abnormality degree in a case where it is determined that the number of abnormality occurrences does not exceed the threshold may be the same or different.

Further, the predetermined value to be added to abnormality degree of a state item for which it is determined that the number of abnormality occurrences does not exceed the threshold and the number of abnormality occurrences is one may be higher than the predetermined value to be added to abnormality degree of a state item for which it is determined that the number of abnormality occurrences does not exceed the threshold and the number of abnormality occurrences is two or more. By this, an abnormal state item that occurs for the first time can be presented to an administrator as a monitored state item.

Processing in Step S98 and Step S99 is the same as the processing in Step S67 and Step S68 in FIG. 14, and will be omitted from description.

Further, in Modification Example 10 of the present embodiment, in a case where a plurality of monitored state items are determined, the display part 34 may display each of the plurality of monitored state items in different modes according to a level of abnormality degree associated with each of the plurality of monitored state items.

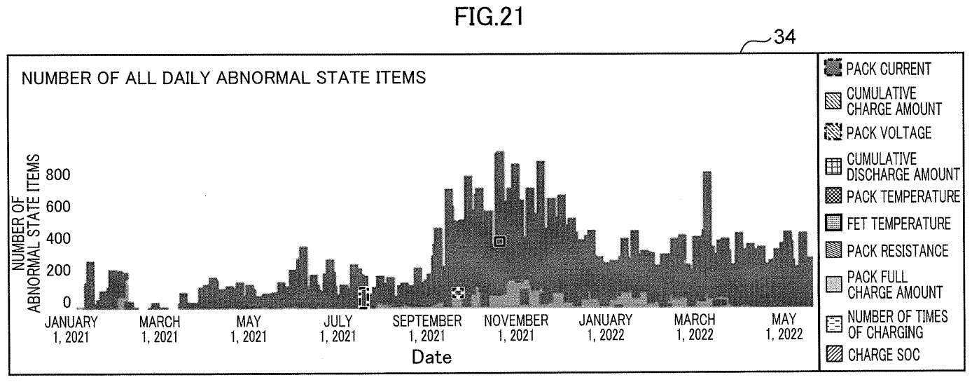

FIG. 21 is a diagram illustrating an example of an abnormal state item display screen displaying a plurality of abnormal state items and a plurality of monitored state items in Modification Example 10 of the present embodiment.

The display part 34 displays the abnormal state item display screen illustrated in FIG. 21. The abnormal state item display screen includes a bar graph indicating the number of abnormal state items occurring in the first predetermined period. The vertical axis represents the number of abnormal state items, and the horizontal axis represents year, month, and day. The bar graphs are stacked by being color-coded in accordance with abnormal state items. The abnormal state item illustrated in FIG. 21 is the same as the abnormal state item illustrated in FIG. 4.

In a case where a plurality of monitored state items are determined, the display part 34 may display each of the plurality of monitored state items in different modes according to a level of abnormality degree associated with each of the plurality of monitored state items. In FIG. 21, the monitored state item having the highest abnormality degree is FET temperature, the monitored state item having the second highest abnormality degree is pack current, and the monitored state item having the third highest abnormality degree is pack voltage. The display part 34 highlights three monitored state items. The display part 34 highlights the monitored state items by surrounding the periphery of each of the three monitored state items with frames of different colors. Colors of frames are, for example, red, blue, and green, and colors of frames surrounding the three monitored state items are different from colors of the other abnormal state items. In FIG. 21, a red frame surrounding the monitored state item having the highest abnormality degree is represented by a solid line, a blue frame surrounding the monitored state item having the second highest abnormality degree is represented by a dotted line, and a green frame surrounding the monitored state item having the third highest abnormality degree is represented by a one-dot chain line.

Further, the display part 34 may display the three monitored state items in chromatic colors such as red, blue, and green, and display the other abnormal state items in achromatic colors such as white, gray, or black, so as to highlight the three monitored state items.

Further, the display part 34 may highlight the monitored state items by surrounding the periphery of each of the three monitored state items with frames of different line types. The line types of frames are, for example, a solid line, a dotted line, and a one-dot chain line. In FIG. 21, the frame surrounding the monitored state item having the highest abnormality degree is a solid line, the frame surrounding the monitored state item having the second highest abnormality degree is a dotted line, and the frame surrounding the monitored state item having the third highest abnormality degree is a one-dot chain line.

Further, in Modification Example 11 of the present embodiment, the communication part 31 of the information terminal 3 may acquire an operation history of each of a plurality of abnormal state items, and the display part 34 may display a plurality of operation histories of a plurality of abnormal state items of one battery, and display an operation history of a monitored state item among the plurality of operation histories in a mode different from other operation histories.

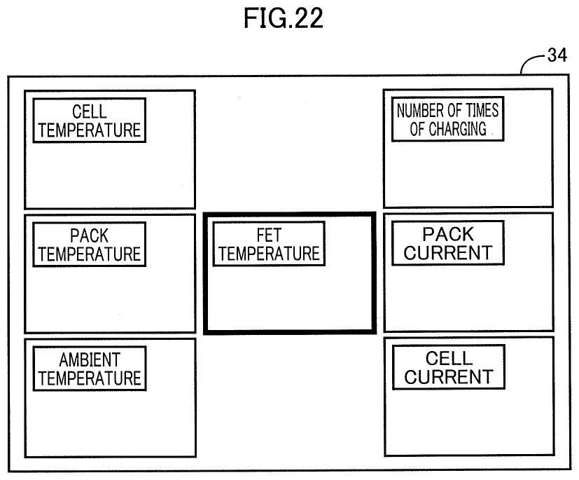

FIG. 22 is a diagram illustrating an example of an operation history display screen displaying a plurality of abnormal state items and an operation history of one monitored state item in Modification Example 11 of the present embodiment.

In Step S32 in FIG. 2, after a plurality of abnormal state items are displayed and a monitored state item among the plurality of abnormal state items is displayed in a mode different from other abnormal state items, the controller 32 receives selection of one monitored state item by an administrator. The communication part 31 transmits, to the server 2, a data request for requesting operation histories of a plurality of abnormal state items of one battery corresponding to the one selected monitored state item. The communication part 21 of the server 2 receives the data request transmitted by the information terminal 3. The controller 22 acquires, from the memory 23, operation histories of a plurality of abnormal state items of one battery corresponding to one monitored state item included in the data request received by the communication part 21. The communication part 21 transmits the operation histories of a plurality of abnormal state items of one battery acquired by the controller 22 to the information terminal 3. The communication part 31 of the information terminal 3 receives the operation histories of a plurality of abnormal state items of one battery transmitted by the server 2. The display part 34 displays a plurality of operation histories of a plurality of abnormal state items of one battery, and displays an operation history of a monitored state item among the plurality of operation histories in a mode different from other operation histories.

Note that in Step S306 of FIG. 7, after a plurality of abnormal state items of one battery are displayed and a monitored state item among the plurality of abnormal state items of one battery is displayed in a mode different from other abnormal state items, the controller 32 may receive selection of one monitored state item by an administrator. Processing after one monitored state item is selected is the same as described above.

The display part 34 displays operation histories of a plurality of abnormal state items of one battery, and highlights an operation history of a monitored state item among the plurality of abnormal state items. In FIG. 22, cell temperature, pack temperature, ambient temperature, the number of times of charging, pack current, cell current, and FET temperature are abnormal state items. Further, FET temperature is a monitored state item. The display part 34 highlights an operation history of a monitored state item by displaying the operation history of the monitored state item at the center.

Further, the display part 34 may highlight an operation history of a monitored state item by surrounding the periphery of the operation history of the monitored state item with a frame of a predetermined color. The predetermined color is, for example, red, and a color of a frame surrounding an operation history of a monitored state item is different from colors of frames surrounding operation histories of other abnormal state items. Further, the display part 34 may display a frame surrounding an operation history of a monitored state item thicker than frames surrounding operation histories of other abnormal state items.

Note that the display part 34 may change a position of an operation history of a monitored state item in a display order. For example, the display part 34 may display an operation history of a monitored state item with a higher priority than operation histories of other abnormal state items. Further, the display part 34 may change a position where an operation history of a monitored state item is displayed. Further, the display part 34 may change size of displaying an operation history of a monitored state item. For example, the display part 34 may display an operation history of a monitored state item larger than operation histories of other abnormal state items.

Further, the display part 34 may set luminance of an operation history of a monitored state item to be displayed to be higher than luminance of operation histories of other abnormal state items to be displayed.

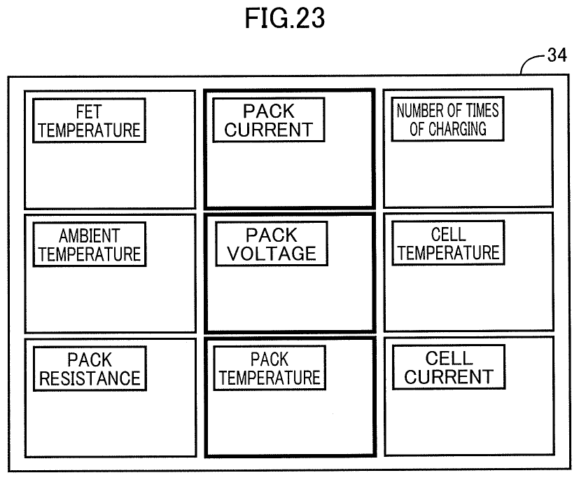

FIG. 23 is a diagram illustrating a first display example of an operation history display screen displaying operation histories of a plurality of monitored state items and a plurality of abnormal state items in Modification Example 12 of the present embodiment.

The display part 34 displays operation histories of a plurality of abnormal state items of one battery, and highlights operation histories of a plurality of monitored state items among the plurality of abnormal state items. In FIG. 23, FET temperature, ambient temperature, pack resistance, the number of times of charging, cell temperature, cell current, pack current, pack voltage, and pack temperature are abnormal state items. Further, pack current, pack voltage, and pack temperature are monitored state items. In a case where a plurality of monitored state items are determined, the display part 34 displays operation histories of a plurality of monitored state items at the center of the screen to highlight the operation histories of the plurality of monitored state items.

Further, the display part 34 may highlight operation histories of a plurality of monitored state items by surrounding the periphery of the operation histories of the monitored state items with frames of a predetermined color. The predetermined color is, for example, red, and a color of frames surrounding operation histories of a plurality of monitored state items is different from a color of frames surrounding operation histories of other abnormal state items. Further, the display part 34 may display frames surrounding operation histories of a plurality of monitored state items thicker than frames surrounding operation histories of other abnormal state items.

A human tends to focus on the center of the screen. In Modification Example 12 of the present embodiment, since operation histories of a plurality of monitored state items are displayed at the center of the screen, it is possible to attract the line of sight of an administrator to the monitored state items while allowing the administrator to overview the whole.

Note that the display part 34 may change positions of operation histories of a plurality of monitored state items in a display order. For example, the display part 34 may display operation histories of a plurality of monitored state items with a higher priority than operation histories of other abnormal state items. Further, the display part 34 may change size of displaying operation histories of a plurality of monitored state items. For example, the display part 34 may display operation histories of a plurality of monitored state items larger than operation histories of other abnormal state items.

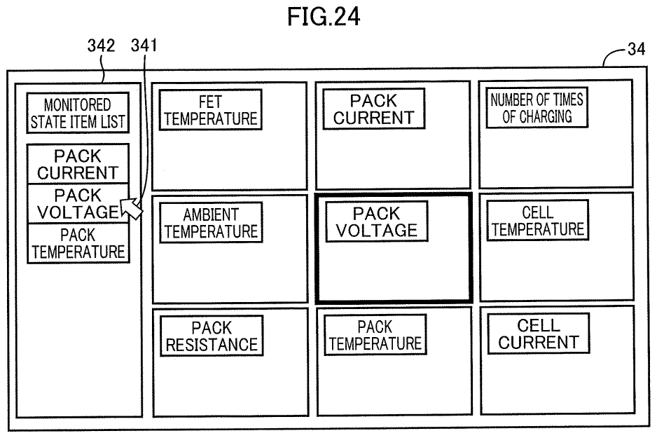

FIG. 24 is a diagram illustrating a second display example of an operation history display screen displaying operation histories of a plurality of monitored state items and a plurality of abnormal state items in Modification Example 12 of the present embodiment.

The display part 34 displays operation histories of a plurality of abnormal state items of one battery, and displays a list 342 of a plurality of monitored state items among the plurality of abnormal state items.

The list 342 is displayed on the left side of an operation history display screen and includes names of a plurality of monitored state items. A plurality of monitored state items displayed in the list 342 can be selected. In FIG. 24, pack current, pack voltage, and pack temperature are monitored state items. For example, an administrator moves a pointer 341 on the screen by operating a mouse (not illustrated) and clicks on a desired monitored state item. Alternatively, for example, in a case where the display part 34 is a touch panel, an administrator touches a desired monitored state item. By selecting a desired monitored state item, one monitored state item among a plurality of monitored state items of one battery is selected.

Then, an operation history corresponding to the one selected monitored state item is displayed in a mode different from operation histories of other abnormal state items. The display part 34 may highlight the operation history of the one selected monitored state item by surrounding the periphery of the operation history of the one selected monitored state item with a frame of a predetermined color. The predetermined color is, for example, red, and a color of a frame surrounding the operation history of the one selected monitored state item is different from colors of frames surrounding operation histories of other abnormal state items. Further, the display part 34 may display a frame surrounding the operation history of the one selected monitored state item thicker than frames surrounding operation histories of other abnormal state items.

In FIG. 24, a monitored state item which is pack voltage is selected, and the periphery of an operation history corresponding to pack voltage among a plurality of abnormal state items is surrounded by a frame of a predetermined color.

Further, the display part 34 may enlarge and display an operation history of one selected monitored state item.

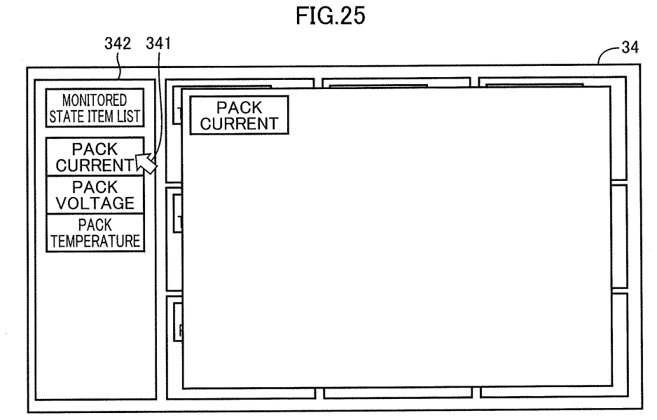

FIG. 25 is a diagram illustrating a third display example of an operation history display screen displaying operation histories of a plurality of monitored state items and a plurality of abnormal state items in Modification Example 12 of the present embodiment.

As illustrated in FIG. 25, in a case where one monitored state item is selected in the list 342, the display part 34 may enlarge and display an operation history of the one monitored state item. In FIG. 25, a monitored state item which is pack current is selected, and an operation history corresponding to pack current is enlarged among a plurality of abnormal state items.

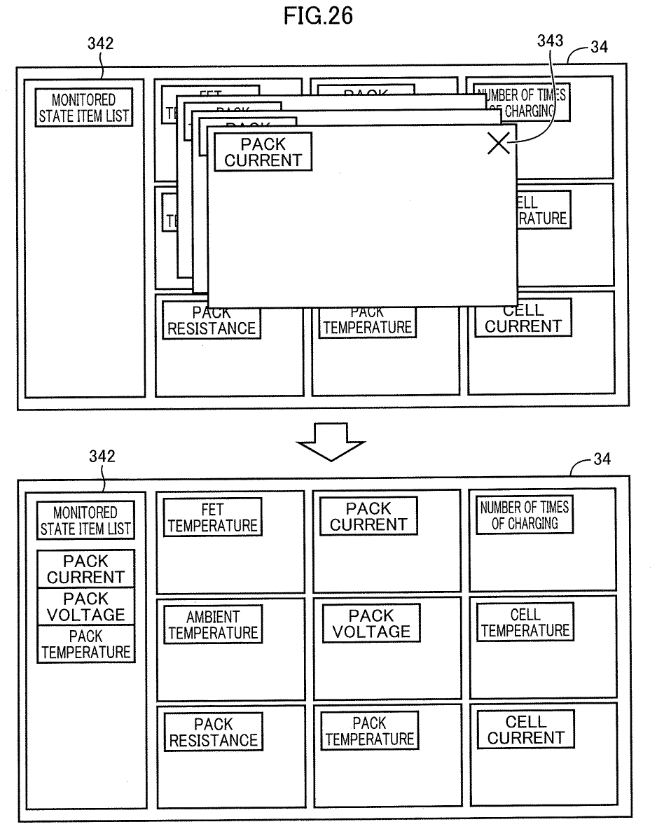

FIG. 26 is a diagram illustrating a fourth display example of an operation history display screen displaying operation histories of a plurality of monitored state items and a plurality of abnormal state items in Modification Example 12 of the present embodiment.

First, the display part 34 displays operation histories of a plurality of abnormal state items of one battery, enlarges operation histories of a plurality of monitored state items among the plurality of abnormal state items, and displays the plurality of enlarged operation histories in an overlapping manner.

In an operation history of a monitored state item, a button 343 for closing the displayed operation history is displayed. After checking an operation history of the displayed monitored state item, an administrator clicks or touches the button 343. When the button 343 is clicked or touched, the operation history of the displayed monitored state item is closed, and the closed monitored state item is displayed in the list 342. When all of operation histories of a plurality of monitored state items are closed, the plurality of monitored state items are displayed in the list 342, and all of operation histories of a plurality of abnormal state items of one battery are displayed. A plurality of monitored state items in the list 342 can be selected, and when one monitored state item among the plurality of monitored state items is selected, an operation history corresponding to the one selected monitored state item is enlarged and displayed.

Note that the display part 34 may vary display modes of operation histories of a plurality of monitored state items based on levels of abnormality degree of a plurality of monitored state items. For example, the display part 34 may display operation histories of a plurality of monitored state items in descending order of abnormality degree of the plurality of monitored state items. For example, the display part 34 may vary colors of frames surrounding the periphery of operation histories of a plurality of monitored state items according to abnormality degree of a plurality of monitored state items. For example, the display part 34 may vary thickness of frames surrounding the periphery of operation histories of a plurality of monitored state items according to abnormality degree of a plurality of monitored state items. The display part 34 may vary size of displaying operation histories of a plurality of monitored state items according to abnormality degree of the plurality of monitored state items.

The periphery of an operation history of a monitored state item having highest abnormality degree may be surrounded by, for example, a red frame, the periphery of an operation history of a monitored state item having the second highest abnormality degree may be surrounded by, for example, a blue frame, and the periphery of an operation history of a monitored state item having the third highest abnormality degree may be surrounded by, for example, a yellow frame. Further, an operation history of the monitored state item having the highest abnormality degree may be displayed larger than an operation history of a monitored state item having the second highest abnormality degree, and the operation history of the monitored state item having the second highest abnormality degree may be displayed larger than an operation history of a monitored state item having the third highest abnormality degree. Further, the operation history of the monitored state item having the third highest abnormality degree may be displayed larger than operation histories of other abnormal state items other than the monitored state items.

In each of the above embodiments, each component may be implemented by being configured with dedicated hardware or by executing a software program suitable for each component. Each component may be implemented by a program execution part, such as a CPU or a processor, reading and executing a software program recorded on a recording medium such as a hard disk or a semiconductor memory. Further, a program may be executed by another independent computer system by recording and transferring the program on a recording medium or transferring the program via a network.

Some or all functions of the devices according to the embodiments of the present disclosure are implemented as Large Scale Integration (LSI) which is typically an integrated circuit. These may be individually integrated into one chip, or may be integrated into one chip so as to include some or all of these. Further, circuit integration is not limited to LSI, and may be implemented by a dedicated circuit or a general-purpose processor. A Field Programmable Gate Array (FPGA) that can be programmed after manufacturing of LSI or a reconfigurable processor in which connection and setting of circuit cells inside the LSI can be reconfigured may be used.

Further, some or all functions of the device according to the embodiment of the present disclosure may be implemented by a processor such as a CPU executing a program.

Further, the numerical figures used above are all illustrated to specifically describe the present disclosure, and the present disclosure is not limited to the illustrated numerical figures.

Further, order in which steps illustrated in the above flowchart are executed is exemplified for specifically describing the present disclosure, and may be any order other than the above order as long as a similar effect is obtained. Further, some of the above steps may be executed simultaneously (in parallel) with other steps.

The technique according to the present disclosure is useful as a technique for displaying a state item for which an abnormal value is detected among a plurality of state items indicating a plurality of states of a battery since it is possible to support determination of an error that occurs in the battery by the user.

1. An information processing method in a computer, the information processing method comprising:
acquiring, from battery log information of a plurality of batteries, a plurality of abnormal state items indicating a state item in which an abnormal value is detected among a plurality of state items indicating a plurality of states of a plurality of batteries; and
displaying the plurality of abnormal state items and displaying a monitored state item, which is an abnormal state item that needs to be handled, among the plurality of abnormal state items, in a mode different from other abnormal state items.

2. The information processing method according to claim 1, further comprising identifying one battery from among the plurality of batteries, wherein the display includes displaying the plurality of abnormal state items of the one battery and displaying the monitored state item among the plurality of abnormal state items in a mode different from the other abnormal state items.

3. The information processing method according to claim 1, further comprising determining, based on a table in which at least one first abnormal state item among the plurality of abnormal state items is associated with at least one second abnormal state item that is the monitored state item, the at least one second abnormal state item associated with the at least one first abnormal state item included in the plurality of acquired abnormal state items as at least one monitored state item.

4. The information processing method according to claim 1, further comprising determining, based on a table in which at least one abnormal state item among the plurality of abnormal state items, an error item indicating an error that occurs in a battery predicted from the at least one abnormal state item, and an importance level of the error item are associated with each other, at least one abnormal state item associated with the error item having the highest importance level among the plurality of acquired abnormal state items as at least one monitored state item.

5. The information processing method according to claim 1, wherein abnormality degree indicating degree of abnormality is associated with each of the plurality of abnormal state items, the information processing method further comprising determining at least one abnormal state item having the maximum abnormality degree among the plurality of acquired abnormal state items as at least one monitored state item.

6. The information processing method according to claim 5, wherein the abnormality degree of each of the plurality of abnormal state items is determined based on degree to which an operation history of each of the plurality of abnormal state items exceeds a threshold.

7. The information processing method according to claim 5, wherein the abnormality degree of each of the plurality of abnormal state items is determined based on time during which an operation history of each of the plurality of abnormal state items continuously exceeds a threshold.

8. The information processing method according to claim 5, wherein
the number of occurrences of the plurality of abnormal state items in a first predetermined period is counted, and
the abnormality degree of each of the plurality of abnormal state items is determined based on degree to which the number of occurrences exceeds a threshold.

9. The information processing method according to claim 8, wherein
one year is divided into a plurality of periods; and
one threshold is selected from among a plurality of different thresholds for each of the plurality of periods according to which of the plurality of periods the first predetermined period is included.

10. The information processing method according to claim 8, wherein
the number of occurrences of the plurality of abnormal state items in a second predetermined period longer than the first predetermined period is counted, and
the abnormality degree of each of the plurality of abnormal state items is decreased in a case where the number of occurrences exceeds a threshold, and is increased in a case where the number of occurrences does not exceed the threshold.

11. The information processing method according to claim 1, wherein abnormality degree indicating degree of abnormality is associated with each of the plurality of abnormal state items, the information processing method further comprising determining at least one abnormal state item having the abnormality degree equal to or more than a threshold among the plurality of acquired abnormal state items as at least one monitored state item.

12. The information processing method according to claim 11, wherein the display includes displaying each of a plurality of monitored state items in a different mode according to a level of the abnormality degree associated with each of the plurality of monitored state items in a case where the plurality of monitored state items is determined.

13. The information processing method according to claim 2, further comprising acquiring an operation history of each of the plurality of abnormal state items, wherein the display includes displaying a plurality of operation histories of the plurality of abnormal state items of the one battery, and displaying an operation history of the monitored state item among the plurality of operation histories in a mode different from the other operation histories.

14. An information processing device comprising:
an acquisition part that acquires, from battery log information of a plurality of batteries, a plurality of abnormal state items indicating a state item in which an abnormal value is detected among a plurality of state items indicating a plurality of states of a plurality of batteries; and
a display part that displays the plurality of abnormal state items and displays a monitored state item, which is an abnormal state item that needs to be handled, among the plurality of abnormal state items, in a mode different from other abnormal state items.

15. A non-transitory computer readable recording medium storing an information processing program that causes a computer to function to:
acquire, from battery log information of a plurality of batteries, a plurality of abnormal state items indicating a state item in which an abnormal value is detected among a plurality of state items indicating a plurality of states of a plurality of batteries; and
display the plurality of abnormal state items and display a monitored state item, which is an abnormal state item that needs to be handled, among the plurality of abnormal state items, in a mode different from other abnormal state items.
